(19) United States
(12) Patent Application Publication
(10) Pub. No.: US 2014/0097009 A1
(43) Pub. Date: Apr. 10, 2014

(54) WIRING SUBSTRATE

(71) Applicant: SHINKO ELECTRIC INDUSTRIES CO., LTD., Nagano-ken (JP)

(72) Inventors: Kentaro KANEKO, Nagano-shi (JP); Kazuhiro KOBAYASHI, Nagano-shi (JP)

(21) Appl. No.: 14/038,190

(22) Filed: Sep. 26, 2013

(30) Foreign Application Priority Data
Oct. 5, 2012 (JP) 2012-222939

(51) Int. Cl. H05K 1/02

(52) U.S. Cl. CPC H05K 1/0296
USPC 174/258; 174/264

(57) ABSTRACT

A wiring substrate includes a first wiring layer, a first insulating layer, a second wiring layer, and a first wiring pattern. The second wiring layer includes a first metal foil that is thinner than the first wiring layer. A first via in the first insulating layer connects the first and second wiring layers. The first via is arranged to fill a first through hole and a first recess. The first through hole extends through the first insulating layer and has a first open end with a first opening diameter and a second open end with a smaller second opening diameter. The first recess is in communication with the first through hole. The first recess has a larger diameter than the second opening diameter. The first metal foil includes a first opening communicating with the first through hole and having a larger opening diameter larger than the first opening diameter.

### CROSS-REFERENCE TO RELATED APPLICATIONS

This application is based upon and claims the benefit of priority from prior Japanese Patent Application No. 2012-222939, filed on Oct. 5, 2012, the entire contents of which are incorporated herein by reference.

### BACKGROUND

This disclosure relates to a wiring substrate and a method for manufacturing a wiring substrate.

Wiring substrates of various shapes and structures are used to mount components such as semiconductor chips and the like. The thinning and miniaturization of semiconductor chips has resulted in demands for a thinner and smaller wiring substrate used for the mounting of semiconductor chips. To manufacture such a wiring substrate, for example, a relatively thin (e.g., thickness of about 40 to 60 μm) core material is used to form filled vias, a wiring, and the like. Japanese Laid-Open Patent Publication No. 2006-049660 and Japanese Laid-Open Patent Publication No. 2009-088429 describe a wiring substrate including filled vias. An example of a method for forming a filled via and wiring will be described below.

As illustrated in FIG. 19A, a core material 90 including two opposite surfaces to which copper foils 91, 92 are adhered is first prepared. Then, in the step illustrated in FIG. 19B, a laser processing method is used to form an opening 92X in the copper foil 92 and to form a through hole 90X, which communicates with the opening 92X and extends through the core material 90 to expose the copper foil 91. In the step illustrated in FIG. 19C, a seed layer 93 is formed to cover an inner wall surface of the through hole 90X (exposed surface of the core material 90) and the exposed surfaces of the copper foils 91, 92 through the opening 92X and the through hole 90X. As illustrated in FIG. 19D, an electrolytic plating method is performed using the seed layer 93 and the copper foil 91 as plating power supply layers. This forms a filled via 94 that fills the through hole 90X, a conductive layer 95 that covers the filled via 94 and the copper foil 92, and a conductive layer 96 that covers the entire lower surface of the copper foil 91. In the step illustrated in FIG. 19E, the copper foil 92 and the conductive layer 95 are patterned to form a wiring layer 97 on the upper surface of the core material 90, and the copper foil 91 and the conductive layer 96 are patterned to form a wiring layer 98 on the lower surface of the core material 90. A subtractive method and the like are used for the patterning of the copper foils 91, 92 and the conductive layers 95, 96. In this manufacturing method, the wiring layers 97, 98 electrically connected by the filled via 94 are formed on both upper and lower surfaces of the core material 90.

In the manufacturing steps described above, laser processing proceeds faster in the core material 90 (resin layer) than in the copper foil 92 when the opening 92X and the through hole 90X are formed by the laser processing method. Thus, as illustrated in FIG. 19B, the through hole 90X of the core material 90 is formed extending into the lower side of the copper foil 92 from the opening 92X. In other words, an overhang structure is formed at the upper part of the through hole 90X. The overhang structure is a structure in which a collar portion 92A of the copper foil 92 projects to the inner side of the through hole 90X, When the filled via 94 includes the overhang structure (collar portion 92A), a plating is deposited from the collar portion 92A of the copper foil 92. Thus, a void easily forms in the filled via 94. For example, as illustrated in FIG. 20, when the plating is deposited from the collar portion 92A of the copper foil 92, a lid plating 95A that closes the through hole 90X easily forms in the vicinity of the opening 92X before the through hole 90X is completely filled with a conductive layer 94A. Thus, a void 99 tends to easily form in the conductive layer 94A (filled via 94).

### SUMMARY

One aspect of the present invention is a wiring substrate including a first wiring layer that is a single metal layer. A first insulating layer is arranged on an upper surface of the first wiring layer. A second wiring layer is arranged on the first insulating layer. The second wiring layer includes a first metal foil, which is thinner than the first wiring layer, and a first wiring pattern. A second insulating layer is arranged on a lower surface of the first wiring layer. A third wiring layer is arranged on the second insulating layer. The third wiring layer includes a second metal foil, which is thinner than the first wiring layer, and a second wiring pattern. A first via is arranged in the first insulating layer to electrically connect the first wiring layer and the second wiring layer. A second via is arranged in the second insulating layer to electrically connect the first wiring layer and the third wiring layer. The first via is arranged to fill a first through hole and a first recess. The first through hole extends through the first insulating layer. The first through hole includes a first open end, which faces the second wiring layer and has a first opening diameter, and a second open end, which faces the first wiring layer and has a second opening diameter. The second opening diameter is smaller than the first opening diameter. The first recess is arranged in the upper surface of the first wiring layer in communication with the first through hole. The first recess has a diameter that is larger than the second opening diameter. The second via is arranged to fill a second through hole and a second recess. The second through hole extends through the second insulating layer. The second through hole includes a third open end, which faces the third wiring layer and has a third opening diameter, and a fourth open end, which faces the first wiring layer and has a fourth opening diameter. The fourth opening diameter is smaller than the third opening diameter. The second recess is arranged in the lower surface of the first wiring layer in communication with the second through hole. The second recess has a diameter that is larger than the fourth opening diameter. The first metal foil includes a first opening, which is in communication with the first through hole and has an opening diameter that is larger than or equal to the first opening diameter. The second metal foil includes a second opening, which is in communication with the second through hole and has an opening diameter that is larger than or equal to the third opening diameter.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1A is a schematic cross-sectional view illustrating a first embodiment of a wiring substrate;

FIG. 1B is an enlarged cross-sectional view illustrating part of the wiring substrate of FIG. 1A;

FIG. 2 is a schematic cross-sectional view illustrating a semiconductor device including the wiring substrate of FIG. 1A;

FIGS. 3A to 3E, 4A to 4D, 5A to 5C, 6A to 6C, 7A, 7B, 8A, 8B, 9A, and 9B are schematic cross-sectional views illustrating a method for manufacturing the wiring substrate of the first embodiment, where FIG. 4B is an enlarged cross-sectional view illustrating part of FIG. 4A and FIG. 5B is an enlarged cross-sectional view illustrating part of FIG. 5A;

FIG. 10 is a schematic cross-sectional view illustrating a method for manufacturing the semiconductor device of FIG. 2;

FIGS. 11A to 11E, 12A to 12E, 13A to 13C, 14A to 14C, 15A, 15B, 16A, and 16B are schematic cross-sectional views illustrating a second embodiment of a method for manufacturing a wiring substrate;

FIG. 17 is a schematic cross-sectional view illustrating a modification of a wiring substrate;

FIG. 18 is a schematic cross-sectional view illustrating a further modification of a wiring substrate;

FIGS. 19A to 19E are schematic cross-sectional views illustrating a method for manufacturing a wiring substrate in the related art; and

FIG. 20 is a schematic cross-sectional view illustrating a void formed in the wiring substrate of the related art.

### DESCRIPTION OF THE EMBODIMENTS

Various embodiments will now be described with reference to the accompanying drawings. Elements in the drawings are illustrated for simplicity and clarity and have not necessarily been drawn to scale. The cross-sectional views include elements that are shaded for clarity, such as insulating layers.

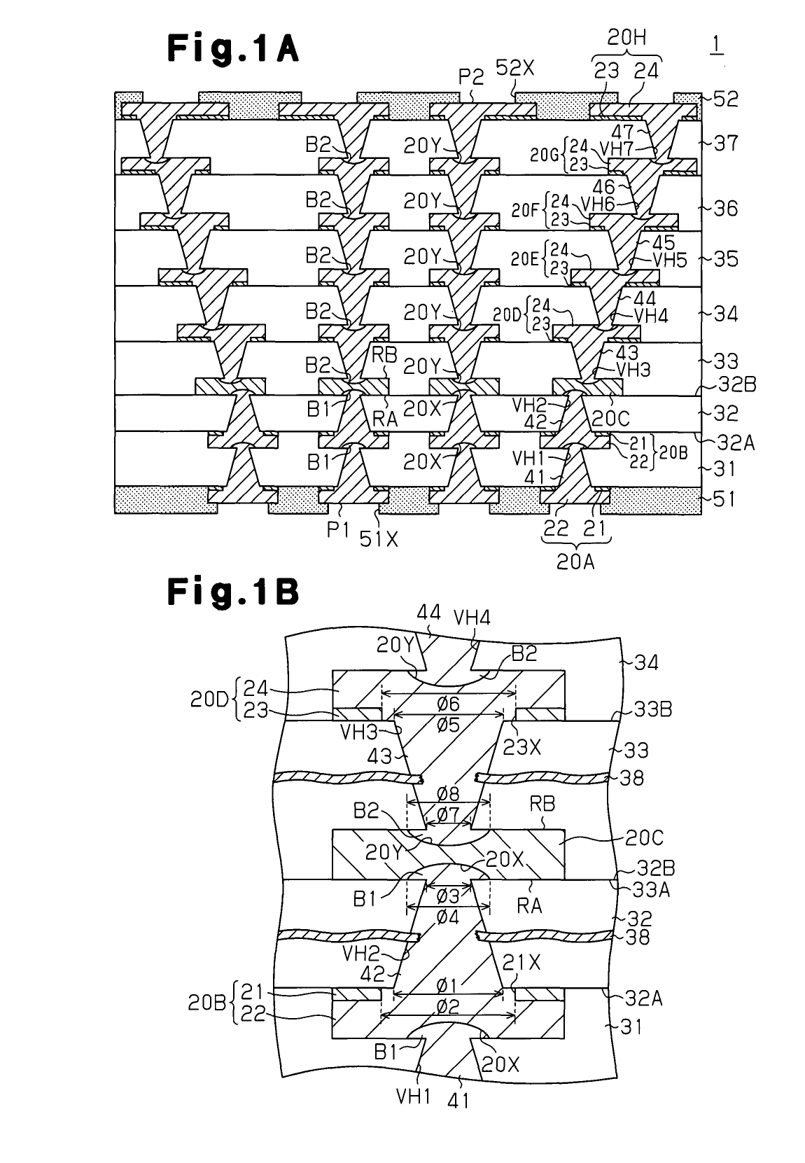

A first embodiment will now be described with reference to FIGS. 1A to 10.

As illustrated in FIG. 1A, a wiring substrate 1 includes wiring layers and insulating layers, which are alternately stacked. The wiring layers are electrically connected by a via arranged in each insulating layer. In the wiring substrate 1 of the present example, eight wiring layers 20A, 20B, 20C, 20D, 20E, 20F, 20G, and 20H and seven insulating layers 31 to 37 are alternately stacked. The wiring layers 20A to 20H are electrically connected by vias 41 to 47 arranged in the insulating layers 31 to 37.

The outermost (here, lowermost) wiring layer 20A is stacked on a lower surface of the outermost (here, lowermost) insulating layer 31. The wiring layer 20B is stacked on a lower surface 32A of the insulating layer 32 stacked on an upper surface of the insulating layer 31. The wiring layer 20A is electrically connected to the wiring layer 20B by the via 41 filled in a through hole VH1 formed in the insulating layer 31. The wiring layer 20C is formed on an upper surface 32B of the insulating layer 32. The wiring layer 20B is electrically connected to the wiring layer 20C by the via 42 filled in a through hole VH2 formed in the insulating layer 32. The wiring layer 20D is stacked on an upper surface of the insulating layer 33 stacked on the upper surface 32B of the insulating layer 32. The wiring layer 20C is electrically connected to the wiring layer 20D by the via 43 filled in a through hole VH3 formed in the insulating layer 33. The wiring layer 20E is stacked on an upper surface of the insulating layer 34. The wiring layer 20D is electrically connected to the wiring layer 20E by the via 44 filled in a through hole VH4 formed in the insulating layer 34. The wiring layer 20F is stacked on an upper surface of the insulating layer 35. The wiring layer 20E is electrically connected to the wiring layer 20F by the via 45 filled in a through hole VH5 formed in the insulating layer 35. The wiring layer 20G is stacked on an upper surface of the insulating layer 36. The wiring layer 20F is electrically connected to the wiring layer 20G by the via 46 filled in a through hole VH6 formed in the insulating layer 36. The outermost (here, uppermost) wiring layer 20H is stacked on an upper surface of the outermost (here, uppermost) insulating layer 37. The wiring layer 20G is electrically connected to the wiring layer 20H by the via 47 filled in a through hole VH7 formed in the insulating layer 37.

The insulating layers 31 to 37 may use glass epoxy resin obtained by curing thermosetting insulating resin having epoxy resin, which is impregnated in a glass cloth (glass fabric cloth), as the main component, for example. The glass cloth is used as a reinforcement material. However, the thermosetting insulating resin is not limited to epoxy resin, and for example, may be polyimide resin, cyanate resin, and the like. Each insulating layer 31 to 37 includes a given number of (one in FIG. 1B) glass cloth 38. For example, the glass cloth 38 has a configuration in which glass fiber bundles arranged side by side in a first direction and glass fiber bundles arranged side by side in a second direction orthogonal to the first direction as viewed from above are plain woven to a lattice-form. Each glass fiber bundle is obtained by bundling a plurality of glass fibers. The diameter of each glass fiber is, for example, about 1 to 2 μm. The thickness of each glass fiber bundle is, for example, about 5 to 10 μm. Other than the glass cloth 38 using the glass fiber bundles, woven cloth or non-woven cloth using carbon fiber bundle, polyester fiber bundle, nylon fiber bundle, aramid fiber bundle, liquid crystal polymer (LCP), and the like may be used for the reinforcement material. The weaving manner of the fiber bundles is not limited to plain weaving, and may be sateen weaving, twill weaving, and the like.

As illustrated in FIG. 1B, the glass cloth 38 arranged in each insulating layer 31 to 37 has an end that extends through the inner wall of the corresponding through hole VH1 to VH7 and projects out into the through hole VH1 to VH7.

As illustrated in FIG. 1A, with the wiring layer 20C serving as a boundary, the stacking structure of the wiring layer and the insulating layer, as well as the structure of the via (through hole) differ between the upper side of the wiring layer 20C and the lower side of the wiring layer 20C. The structure of the wiring layer 20C and the periphery of the wiring layer 20C will now be described.

As illustrated in FIG. 1B, the wiring layer 20C is stacked on the upper surface 32B of the insulating layer 32. The insulating layer 33 that covers the wiring layer 20C is also stacked on the upper surface 32B of the insulating layer 32. In other words, a lower surface RA of the wiring layer 20C is covered by the insulating layer 32, and an upper surface RB, as well as the side surfaces of the wiring layer 20C, is covered by the insulating layer 33.

The wiring layer 20B is stacked on a lower surface 32A of the insulating layer 32 formed on the lower side than the wiring layer 20C. The wiring layer 20B includes a metal foil 21 formed on the lower surface 32A of the insulating layer 32, and a wiring pattern 22 formed on the lower surface of the via 42 to cover the metal foil 21. The through hole VH2 includes a first open end, which faces the wiring layer 20B and has an opening diameter Φ1, and a second open end, which faces the wiring layer 20C and has an opening diameter Φ3. The metal foil 21 includes an opening 21X having an opening diameter Φ2 wider than the opening diameter Φ1 of the first open end of the through hole VH2 (diameter of the lower surface of the via 42). The opening 21X communicates with the through hole VH2 and exposes part of the lower surface 32A of the insulating layer 32 contacting the inner wall of the through hole VH2. The opening diameter Φ2 of the opening 21X of the metal foil 21 may be set to the same size as the opening diameter Φ1.

The wiring layer 20B on the lower side of the wiring layer 20C is configured from two metal layers, i.e., the metal foil 21 and the wiring pattern 22, whereas the wiring layer 20C is configured only from one metal layer. Copper and copper alloy, for example, may be used as the material of the wiring layer 20C and the wiring layer 20B (metal foil 21 and wiring pattern 22). The metal foil 21 and the wiring pattern 22 may be of the same material or of a different material.

The thickness of the wiring layer 20C is set to be thicker than the metal foil 21. For example, the thickness of the wiring layer 20C is set to be substantially the same as the thickness from the upper surface of the metal foil 21 to the lower surface of the wiring pattern 22. The thickness of the wiring layer 20C may be, for example, about 15 to 35 μm. The thickness of the metal foil 21 may be, for example, about 6 to 12 μm. The thickness from the lower surface of the metal foil 21 to the lower surface of the wiring pattern 22 is, for example, about 9 to 29 μm. The thickness of the insulating layer 32 may be, for example, 40 to 60 μm. The opening diameter Φ1 of the through hole VH2 may be, for example about 75 to 90 μm. The opening diameter Φ2 of the opening 21X may be, for example, about 75 to 100 μm.

As illustrated in FIG. 1B, the through hole VH2 is tapered such that the diameter reduces from the first open end (lower end in FIG. 1B) facing the wiring layer 20B toward the second open end (upper end in FIG. 1B) facing the wiring layer 20C. In other words, the through hole VH2 has a circular truncated cone shape in which an opening diameter Φ3 of the second open end is smaller than the opening diameter Φ1 of the first open end. A recess 20X formed in the lower surface RA of the wiring layer 20C is exposed from the second open end (upper end) of the through hole VH2.

The recess 20X communicates with the through hole VH2. The recess 20X extends from the lower surface RA of the wiring layer 20C to a halfway position in the thickness direction of the wiring layer 20C. Therefore, the recess 20X has a bottom surface located halfway in the thickness direction of the wiring layer 20C. The recess 20X has an opening diameter Φ4 wider than the diameter Φ3 of the second open end of the through hole VH2. Therefore, an outermost edge of the inner wall of the recess 20X is located at the outer side of an innermost edge of the inner wall of the through hole VH2. Thus, the outer edge of the recess 20X extends to the upper part of the insulating layer 32. That is, the recess 20X exposes part of the upper surface 32B of the insulating layer 32 contacting the inner wall of the through hole VH2.

The recess 20X is, for example, formed to have a substantially semi-elliptical cross-section. The depth of the recess 20X is, for example, about 3 to 4 μm. The opening diameter Φ3 of the through hole VH2 is, for example, about 50 to 80 μm. The opening diameter Φ4 of the recess 20X is, for example, about 60 to 90 μm.

The via 42 is filled in the through hole VH2 and the recess 20X. The portion of the via 42 filled in the recess 20X serves as an end B1 of the via 42. The end B1 of the via 42 is joined with the wiring layer 20C on the upper side than the lower surface RA of the wiring layer 20C. The portion of the via 42 filled in the through hole VH2 is tapered so that the diameter reduces from the end facing the wiring layer 20B toward the end facing the wiring layer 20C (recess 20X). The via 42 also covers the entire surface of the end of the corresponding glass cloth 38 projecting to the inner side from the inner wall of the through hole VH2.

In a space including the through hole VH2 and the recess 20X, that is, a forming space of the via 42, part of the inner wall of the through hole VH2 projects at the lower side of the recess 20X. Thus, a step is formed by the inner wall of the through hole VH2, the upper surface 32B of the insulating layer 32 exposed in the recess 20X, and the inner wall of the recess 20X. When the via 42 is formed in the space having such a step, the via 42 extends on the upper surface 32B of the insulating layer 32 exposed in the recess 20X. Therefore, the end B1 of the via 42 has the shape of a nail head or a screw head, and the lower surface of the edge of the end B1 contacts the upper surface 32B of the insulating layer 32.

The wiring layer 20D is stacked on the upper surface 33B of the insulating layer 33. The wiring layer 20D includes a metal foil 23 formed on the upper surface 33B of the insulating layer 33, and a wiring pattern 24 formed on the upper surface of the via 43 so as to cover the metal foil 23. In other words, the wiring layer 20D is configured by two metal layers, i.e., the metal foil 23 and the wiring pattern 24. Copper and copper alloy, for example, may be used for the material of the metal foil 23 and the wiring pattern 24. The metal foil 23 and the wiring pattern 24 may be of the same material or of a different material.

The through hole VH3 includes a first open end, which faces the wiring layer 20D and has an opening diameter Φ5, and a second open end, which faces the wiring layer 20C and has an opening diameter Φ7. The metal foil 23 includes an opening 23X having an opening diameter Φ6 wider than the opening diameter Φ5 of the first open end of the through hole VH3 (diameter of the upper surface of the via 43). The opening 23X communicates with the through hole VH3 and exposes part of the upper surface 33B of the insulating layer 33 contacting the inner wall of the through hole VH3. The opening diameter Φ6 of the opening 23X of the metal foil 23 may be set to the same size as the opening diameter Φ5.

The thickness of the wiring layer 20C is set to be thicker than the metal foil 23. For example, the thickness of the wiring layer 20C is set to substantially the same thickness as the thickness from the lower surface of the metal foil 23 to the upper surface of the wiring pattern 24. The thickness of the metal foil 23 may be, for example, about 6 to 12 μm. The thickness from the upper surface of the metal foil 23 to the upper surface of the wiring pattern 24 may be, for example, about 9 to 29 μm. The thickness from the upper surface RB of the wiring layer 20C to the upper surface 33B of the insulating layer 33 may be, for example, 40 to 60%. The opening diameter Φ5 of the through hole VH3 may be, for example about 75 to 90 μm. The opening diameter Φ6 of the opening 23X may be, for example, about 75 to 100 μm.

The through hole VH3 is tapered so that the diameter reduces from the first open end (upper end in FIG. 1B) facing the wiring layer 20D toward the second open end (lower end in FIG. 1B) facing the wiring layer 20C. In other words, the through hole VH3 has an inverted circular truncated cone shape in which the opening diameter Φ7 of the second open end is smaller than the opening diameter Φ5 of the first open end. Thus, the through hole VH3 having an inverted circular truncated cone shape is formed on the upper side than the upper surface RB of the wiring layer 20C, and the through hole VH2 having a circular truncated cone shape is formed on the lower side than the lower surface RA of the wiring layer 20C. A recess 20Y formed in the upper surface RB of the wiring layer 20C is exposed from the second open end (lower end) of the through hole VH3.

The recess 20Y communicates with the through hole VH3. The recess 20Y extends from the upper surface RB of the wiring layer 20C to a halfway position in the thickness direction of the wiring layer 20C. Therefore, the recess 20Y has a bottom surface positioned halfway in the thickness direction of the wiring layer 20C. The recess has an opening diameter Φ8 wider than the diameter Φ7 of the second open end of the through hole VH3. Therefore, the outermost edge of the inner wall of the recess 20Y is positioned on the outer side than innermost edge of the inner wall of the through hole VH3. The outer edge of the recess 20Y thus extends to the lower part of the insulating layer 33. In other words, the recess 20Y exposes part of the lower surface of the insulating layer 33 contacting the inner wall of the through hole VH3.

The recess 20Y is, for example, formed to have a substantially semi-elliptical cross-section. The depth of the recess 20Y is, for example, about 3 to 4 μm. The opening diameter Φ7 of the through hole VH3 is, for example, about 50 to 80 μm. The opening diameter Φ8 of the recess 20Y is, for example, about 60 to 90 μm.

The via 43 is filled in the through hole VH3 and the recess 20Y. The portion of the via 43 filled in the recess 20Y serves as an end B2 of the via 43. The end B2 of the via 43 is joined with the wiring layer 20C on the lower side than the upper surface RB of the wiring layer 20C. The portion of the via 43 filled in the through hole VH3 is tapered so that the diameter reduces from the end facing the wiring layer 20D toward the end facing the wiring layer 20C (recess 20Y). The via 43 also covers the entire surface of the end of the corresponding glass cloth 38 projecting to the inner side from the inner wall of the through hole VH3.

In a space including the through hole VH3 and the recess 20Y, that is, a forming space of the via 43, part of the inner wall of the through hole VH3 projects above the recess 20Y. Thus, a step is formed by the inner wall of the through hole VH3, the lower surface of the insulating layer 33 exposed in the recess 20Y, and the inner wall of the recess 20Y. When the via 43 is formed in the space having such a step, the via 43 extends on the lower surface of the insulating layer 33 exposed in the recess 20Y. Therefore, the end B2 of the via 43 has the shape of a nail head or a screw head, and the upper surface of the edge of the end B2 contacts the lower surface of the insulating layer 33.

Therefore, the recess 20X is formed in the lower surface RA of the wiring layer 20C, and the recess 20Y is formed in the upper surface RB of the wiring layer 20C. The recesses 20X, 20Y do not communicate in the wiring layer 20C. In other words, the wiring layer 20C is arranged between the recess 20X and the recess 20Y. That is, the thickness of the wiring layer 20C is set so that the recesses 20X, 20Y do not communicate in the wiring layer 20C.

The structure of the wiring substrate 1 will now be described centering on the difference between the structure at the upper side of the wiring layer 20C and the structure at the lower side of the wiring layer 20C.

As illustrated in FIG. 1A, the insulating layer 31 located at the lower side of the insulating layer 32 is stacked on the lower surface 32A of the insulating layer 32 so as to cover the wiring layer 20B. The wiring layer 20A including the metal foil 21 and the wiring pattern 22 is stacked on the lower surface of the insulating layer 31. The metal foil 21 is thinner than the wiring layer 20B.

The through hole VH1 formed in the insulating layer 31 includes a first open end (lower end in FIG. 1A), which faces the wiring layer 20A, and a second open end (upper end in FIG. 1A), which faces the wiring layer 20C. The through hole VH1 is tapered so that the diameter reduces from the first open end toward the second open end. In other words, the through hole VH1 has a circular truncated cone shape in which the opening diameter of the second open end (upper end) is smaller than the opening diameter of the first open end (lower end). The recess 20X formed in the lower surface of the wiring layer 20B is exposed from the second open end (upper end) of the through hole VH1. The recess 20X of the wiring layer 20B communicates with the through hole VH1 in the same manner as the recess 20X of the wiring layer 20C described above, and has a diameter larger than the second open end (upper end) of the through hole VH1.

The via 41 is filled in the through hole VH1 and the recess 20X of the wiring layer 20B. The portion of the via 41 filled in the recess 20X serves as an end B1 of the via 41. The end B1 of the via 41 has the shape of a nail head or a screw head, and the lower surface of the edge of the end B1 contacts the upper surface of the insulating layer 31 that covers the lower surface of the wiring layer 20B.

The insulating layers 34, 35, 36, and 37 located at the upper side of the insulating layer 33 are respectively stacked on the upper surfaces of the insulating layers 33, 34, 35, and 36 so as to cover the wiring layers 20D, 20E, 20F, and 20G stacked on the upper surfaces of the insulating layers 33, 34, 35, and 36. The wiring layers 20E, 20F, 20G, and 20H are respectively stacked on the upper surfaces of the insulating layers 34, 35, 36, and 37. Each wiring layer 20E, 20F, 20G, 20H includes the metal foil 23 and the wiring pattern 24. The metal foil 23 is thinner than the wiring layers 20D, 20E, 20F, and 20G.

The through holes VH4, VH5, VH6, and VH7 formed in the insulating layers 34, 35, 36, and 37 each have a tapered shape in which the diameter reduces from the upper side (wiring layer 20H side) toward the lower side (wiring layer 20C side) in FIG. 1A. That is, in the same manner as the through hole VH3, each through hole VH4 to VH7 has a circular truncated cone shape in which the opening diameter of the open end on the lower side is smaller than the opening diameter of the open end on the upper side. The recess 20Y formed in the upper surface of the wiring layer 20D, 20E, 20F, 20G is exposed from the open end on the lower side of the corresponding through hole VH4, VH5, VH6, VH7. In the same manner as the recess 20Y of the wiring layer 20C, the recess 20Y of the wiring layer 20D, 20E, 20F, 20G communicates with the corresponding through hole VH4, VH5, VH6, VH7, and has a diameter larger than the open end on the lower side of the corresponding through hole VH4, VH5, VH6, VH7.

The vias 44, 45, 46, and 47 are filled in the corresponding through holes VH4, VH5, VH6, VH7, and the recesses 20Y. Thus, the ends B2 of the vias 44 to 47 (portions of the vias 44 to 47 filled in the recesses 20Y) have the shape of a nail head or a screw head. Therefore, the lower surface of the edge of the end B2 of the via 44 to 47 contacts the lower surface of the corresponding insulating layer 34 to 37 that covers the wiring layer 20D, 20E, 20F, 20G.

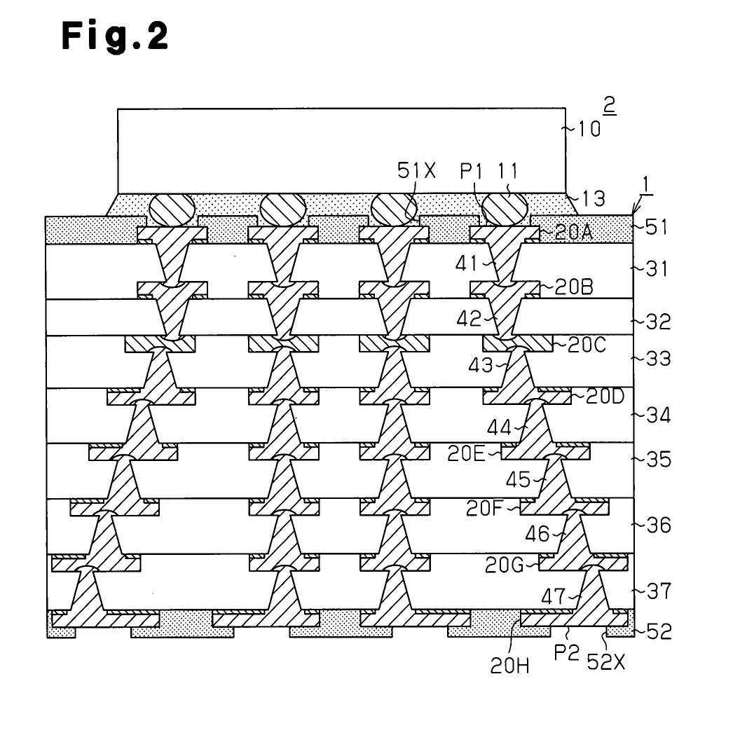

A solder resist layer 51 is stacked on the lower surface of the lowermost insulating layer 31. An insulating resin such as epoxy resin, for example, may be used as the material of the solder resist layer 51. The solder resist layer 51 includes an opening 51X for exposing part of the wiring pattern 22 of the wiring layer 20A as a pad P1. A bump 11 (see FIG. 2) of a semiconductor chip 10 mounted on the wiring substrate 1 is flip-chip connected to the pad P1. In other words, the lower side surface of the wiring substrate 1 including the pad P1 is used as a chip mounting surface. The solder resist layer 51 and the lowermost insulating layer 31 formed on the chip mounting surface are flatter than a solder resist layer 52 and the uppermost insulating layer 37 located at the opposite side of the chip mounting surface.

The organic solderbility preservative (OSP) process may be performed, when necessary, to form an OSP film on the wiring pattern 22 exposed from the opening 51X. In this case, the semiconductor chip 10 is connected to the OSP film. Furthermore, a metal layer may be formed on the wiring pattern 22 exposed from the opening 51X, and the semiconductor chip 10 may be connected to the metal layer. Examples of the metal layer include gold (Au) layer, nickel (Ni)/Au layer (metal layer in which Ni layer and Au layer are sequentially stacked on the wiring pattern 22), Ni/palladium (Pd)/Au layer (metal layer in which Ni layer, Pd layer, and Au layer are sequentially stacked on the wiring pattern 22), or the like.

In the same manner, the insulating resin such as epoxy resin, for example, may be used for the material of the solder resist layer 52 stacked on the upper surface of the uppermost insulating layer 37. The solder resist layer 52 includes an opening 52X for exposing part of the wiring pattern 24 of the wiring layer 20H as an external connection pad P2. An external connection terminal such as a ball, lead pin, and the like, which is used when mounting the wiring substrate 1 on a mounting substrate such as a motherboard, for example, is connected to the external connection pad P2. The OSP processing may be performed, when necessary, to form the OSP film on the wiring pattern 24 exposed from the opening 52X. In this case, the external connection terminal is connected to the OSP film. A metal layer may be formed on the wiring pattern 24 exposed from the opening 52X, and the external connection terminal may be connected to the metal layer. Examples of the metal layer include Au layer, Ni/Au layer, Ni/Pd/Au layer, or the like. The wiring pattern 24 exposed from the opening 52X may be used as the external connection terminal. Alternatively, when the OSP film or the metal layer is formed on the wiring pattern 24, such OSP film or the metal layer may be used as the external connection terminal.

As illustrated in FIG. 2, a semiconductor device 2 includes the wiring substrate 1, the semiconductor chip 10, and an underfill resin 13. The wiring substrate 1 illustrated in FIG. 2 is illustrated with the top and bottom reversed from FIG. 1A.

The semiconductor chip 10 is flip-chip mounted on the wiring substrate 1. In other words, the bump 11 arranged on a circuit forming surface (lower surface in FIG. 2) of the semiconductor chip 10 is joined with the pad P1 of the wiring substrate 1 to join the semiconductor chip 10 to the wiring substrate 1 face-down. The semiconductor chip 10 is electrically connected to the pad P1 of the wiring substrate 1 by the bump 11.

A logic chip such as a central processing unit (CPU) chip, a graphics processing unit (GPU) chip, and the like, for example, may be used for the semiconductor chip 10. A memory chip such as a dynamic random access memory (DRAM) chip, a static random access memory (SRAM) chip, a flash memory chip, and the like, for example, may also be used for the semiconductor chip 10. The size of the semiconductor chip 10 is about 3 mm×3 mm to 12 mm×12 mm, for example, as viewed from above. The thickness of the semiconductor chip 10 is, for example, about 50 to 100 μm.

A gold bump or a solder bump, for example, may be used for the bump 11. An alloy containing lead (Pb), an alloy of tin (Sn) and Au, an alloy of Sn and Cu, an alloy of Sn and Ag, an alloy of Sn, Ag, and Cu, and the like, for example, may be used for the material of the solder bump.

The underfill resin 13 is arranged to fill the gap between the upper surface of the wiring substrate 1 and the lower surface of the semiconductor chip 10. The underfill resin 13 enhances the connection strength of the connecting portion of the bump 11 and the pad P1, and also prevents corrosion of the wiring pattern 22, occurrence of electromigration, and lowering in reliability of the wiring pattern 22. The insulating resin such as epoxy resin, for example, may be used for the material of the underfill resin 13.

The operation of the wiring substrate 1 formed in the above manner will now be described.

The opening diameter Φ2 of the opening 21X of the metal foil 21 is set to be the same as the opening diameter Φ1 or to be larger than the opening diameter Φ1 of the first open end (lower end in FIG. 1B) of the through hole VH2. The opening diameter Φ6 of the opening 23X of the metal foil 23 is set to be the same as the opening diameter Φ5 or to be larger than the opening diameter Φ5 of the first open end (upper end in FIG. 1B) of the through hole VH3. Thus, when forming the vias 42, 43 in the through holes VH2, VH3 by electrolytic plating, the plating is suppressed from being deposited from near the openings 21X, 23X of the metal foils 21, 23. The void is thus suppressed from forming inside the vias 42, 43. Furthermore, when the opening diameters Φ2, Φ6 of the openings 21X, 23X are respectively larger than the opening diameters Φ1, Φ5, part of the lower surface 32A of the insulating layer 32 and part of the upper surface 33B of the insulating layer 33 are exposed in the openings 21X, 23X, respectively. The contacting area of the via 42 and the insulating layer 32, and the contacting area of the via 43 and the insulating layer 33 thus increase. Therefore, the adhesiveness of the via 42 and the insulating layer 32, and the adhesiveness of the via 43 and the insulating layer 33 may be enhanced.

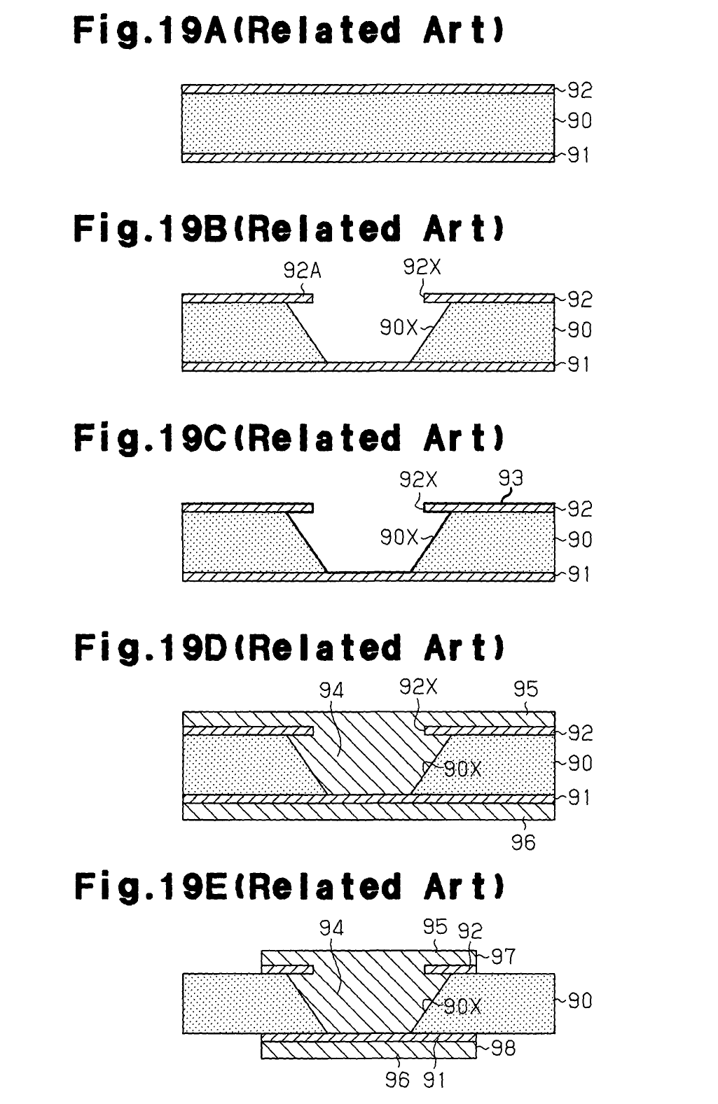

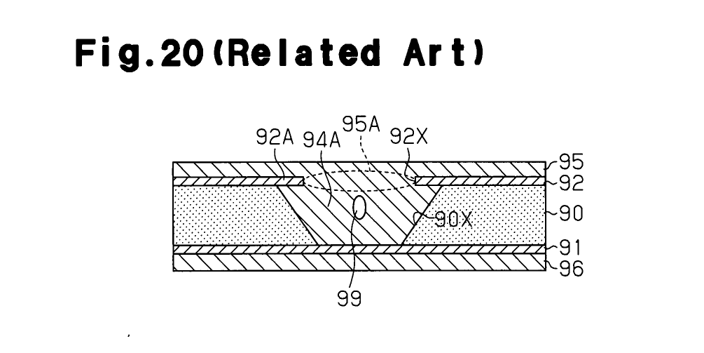

The wiring layer 20C is configured by one metal layer. Therefore, an interface (i.e., interface of the copper foil 91 and the conductive layer 96) formed in the wiring layer 98 illustrated in FIG. 19E thus does not exist in the wiring layer 20C. Thus, the generation of cracks caused by the interface may be prevented. Furthermore, connection failure and formation of void that may occur at the interface may also be prevented, and the occurrence of breakage due to stress caused by the difference in the thermal expansion coefficients of the wiring layer 20C and the insulating layers 32, 33 may be suppressed. Accordingly, the adhesiveness and the connection reliability of the vias 42, 43 and the wiring layer 20C may be further enhanced.

The via 42 joined to the lower surface RA of the wiring layer 20C is filled in the through hole VH2, and the recess 20X, which has a diameter larger than the opening diameter Φ3 of the second open end (upper end in FIG. 1B) of the through hole VH2. Furthermore, the via 43 joined to the upper surface RB of the wiring layer 20C is filled in the through hole VH3, and the recess 20Y, which has a diameter larger than the opening diameter Φ7 of the second open end (lower end in FIG. 1B) of the through hole VH3. The end B1 of the via 42 thus, extends to the upper surface 32B of the insulating layer 32, and the end B2 of the via 43 extends to the lower surface of the insulating layer 33 covering the upper surface RB of the wiring layer 20C. The adhesiveness of the via 42 and the insulating layer 32, and the adhesiveness of the via 43 and the insulating layer 33 thus further enhance. As a result, high adhesiveness may be maintained with respect to the tensile force caused by the difference in the thermal expansion coefficients of the vias 42, 43 and the insulating layers 32, 33. Therefore, the vias 42, 43 may be suppressed from falling out from the through holes VH2, VH3.

Furthermore, the wiring layer 20C is set to a thickness the recess 20X and the recess 20Y do not communicate. In this configuration, the recess 20X and the recess 20Y do not communicate in the wiring layer 20C, and thus the number of interfaces formed in the wiring layer 20C may be reduced. Since a large number of interfaces are not formed in the wiring layer 20C, the generation of cracks at each interface may be prevented. As a result, the connection reliability of the vias 42, 43 and the wiring layer 20C may be further enhanced.

Moreover, the end B1 of the via 42 on the lower side and the end B2 of the via 43 on the upper side are joined with respect to one wiring layer 20C. The thinning of the entire wiring substrate 1 thus may be achieved.

The method for manufacturing the wiring substrate 1 will now be described.

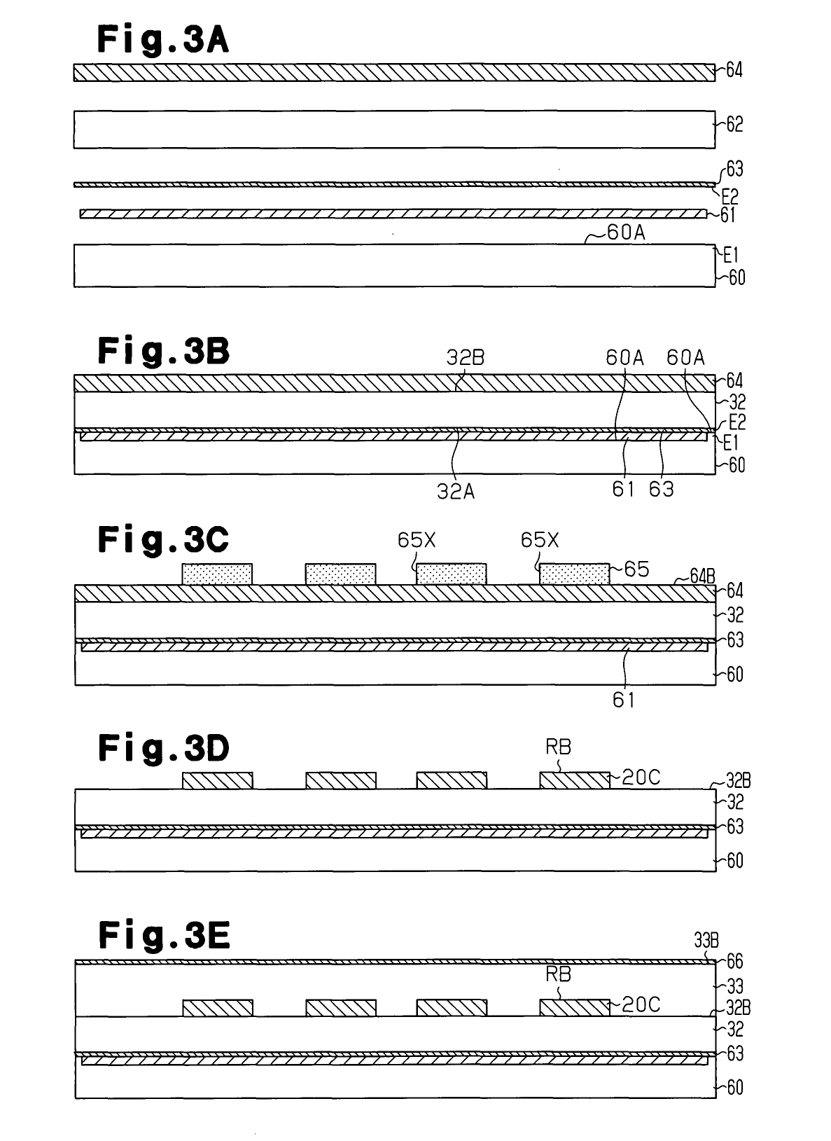

As illustrated in FIG. 3A, a support body 60, an underlayer 61, a metal foil 63, an insulating layer 62, and a metal foil 64 are first prepared. The support body 60 is a prepreg in a half-cured state (B-stage) obtained by impregnating the thermosetting insulating resin such as epoxy resin, polyimide resin, and the like in a reinforcement material such as glass cloth, glass non-woven cloth, aramid woven cloth, and the like. The thickness of the support body 60 may be, for example, about 35 to 400 μm.

A metal foil such as copper foil, and the like, a mold release film or a mold release agent may be used for the underlayer 61. In the present example, the copper foil is used for the underlayer 61. The thickness of the underlayer 61 may be, for example, about 12 to 18 μm. The mold release film may be that in which a thin fluorine contained resin (ETFE) layer is stacked on a film made of polyester, PET (polyethylene terephtalate), and the like, or that in which the silicone mold release is applied on the surface of a film made of polyester, PET, and the like. Silicon mold release agent, fluorine contained mold release agent, and the like may be used for the mold release agent.

The upper surface and the lower surface of the support body 60 are formed to be larger than the upper surface and the lower surface of the underlayer 61. As illustrated in FIG. 3A, for example, the underlayer 61 is arranged at the middle of the support body 60. In this case, an edge E1 of the support body 60 projects from each side of the underlayer 61 toward the outer side. The upper surface of the support body 60 and the upper surface of the underlayer 61 are formed flat.

The insulating layer 62 serving as the insulating layer 32 is a prepreg in a half-cured state obtained by impregnating the thermosetting insulating resin such as epoxy resin, polyimide resin, and the like in a reinforcement material such as glass cloth, glass non-woven cloth, aramid woven cloth, and the like.

The metal foil 64, which is the base material of the wiring layer 20C, is formed to be thicker than the metal foil 63, which is the base material of the metal foil 21 of the wiring layer 20B. Copper and copper alloy, for example, may be used for the material of the metal foils 63, 64.

The insulating layer 62 and the metal foils 63, 64 are set to the same size as the support body 60. Thus, the edge of the insulating layer 62, the edge E2 of the metal foil 63, and the edge of the metal foil 64 project from each side of the underlayer 61 toward the outer side in the same manner as the edge E1 of the support body 60.

As illustrated in FIG. 3A, the underlayer 61, the metal foil 63, the insulating layer 62, and the metal foil 64 are sequentially stacked from the support body 60 on an upper surface 60A (first surface) of the support body 60. The edge E2 of the metal foil 63 and the edge E1 of the support body 60 thus face each other. Subsequently, in the step illustrated in FIG. 3B, the stacked body of the support body 60, the underlayer 61, the metal foil 63, the insulating layer 62, and the metal foil 64 is pressurized from above and below at a temperature of about 190° C. to 200° C. in a depressurized environment (e.g., vacuum atmosphere). The support body 60 is thus cured and the insulating layer 62 is cured, and the insulating layer 32 made from an insulating resin containing a reinforcement material such as glass epoxy resin and the like is obtained. The underlayer 61 and the metal foil 63 are adhered to the upper surface 60A of the support body 60 with the curing of the support body 60. Furthermore, the metal foil 63 is adhered to the lower surface 32A of the insulating layer 32 and the metal foil 64 is adhered to the upper surface 32B of the insulating layer 32 with the curing of the insulating layer 62. In this case, the entire lower surface of the underlayer 61 is adhered to the upper surface 60A of the support body 60, and only the edge E2 of the metal foil 63 is partially adhered to the upper surface 60A of the edge E1 of the support body 60. In a superimposed region of the underlayer 61 and the metal foil 63, the underlayer 61 and the metal foil 63 are merely in contact. Thus, the underlayer 61 and the metal foil 63 may be easily separated in the superimposed region.

When using the mold release agent for the underlayer 61, the mold release agent is applied or sprayed onto the middle of the adhering surface of the metal foil 63 with respect to the support body 60 to form the underlayer 61. Then, the metal foil 63, the insulating layer 62, and the metal foil 64 are stacked on the support body 60 by way of the mold release agent (underlayer 61), and such stacked body is heated and pressurized to adhere the underlayer 61 and the metal foil 63 on the support body 60. The structure is obtained in the same manner as the structure illustrated in FIG. 3B.

In such a structure, the mechanical strength may be sufficiently ensured by the support body 60 even if the insulating layer 32 is thin. Thus, the transportation property of the structure in the manufacturing process may be enhanced, and warping may be suppressed in the structure in the manufacturing process.

Subsequently, in the step illustrated in FIG. 3C, a resist layer 65 having an opening 65X at a given area is formed on an upper surface 64B of the metal foil 64. The resist layer 65 covers the metal foil 64 of a portion corresponding to the wiring layer 20C illustrated in FIG. 1A. In view of the etching processing of the next step, a material having etching resistance property may be used for the material of the resist layer 65. For example, the material of the resist layer 65 may be, for example, photosensitive dry film resist or liquid photoresist (e.g., dry film resist or liquid resist of novolac resin, acrylic resin, etc.). When using the photosensitive dry film resist, for example, the dry film is laminated on the upper surface 64B of the metal foil 64 through thermo-compression, and the laminated dry film is patterned through exposure and development. This forms the resist layer 65 having the opening 65X on the upper surface 64B of the metal foil 64. When using the liquid photoresist as well, the resist layer 65 may be formed through similar steps.

The metal foil 64 is then etched using the resist layer 65 as an etching mask. In other words, the metal foil 64 exposed from the opening 65X of the resist layer 65 is etched to pattern the metal foil 64 to a given shape. The wiring layer 20C of a given shape is thus formed on the upper surface 32B of the insulating layer 32, as illustrated in FIG. 3D. When patterning the metal foil 64 by performing wet etching (isotropic etching), the etchant used in the wet etching may be appropriately selected according to the material of the metal foil 64. For example, aqueous ferric chloride and aqueous copper chloride may be used for the etchant if copper is used for the metal foil 64. For example, the metal foil 64 may be patterned by performing spray etching from the upper surface 64B of the metal foil 64.

As illustrated in FIG. 3D, the resist layer 65 illustrated in FIG. 3C is removed with an alkaline stripping solution, for example. Then, roughening processing of the wiring layer 20C is performed. The roughening processing is performed, for example, so that the roughness degree of the upper surface RB and the side surface of the wiring layer 20C becomes about 0.5 to 2 μm in a surface roughness value Ra. The surface roughness value Ra is an index representing the surface roughness and is referred to as an arithmetic average roughness. The surface roughness value Ra is obtained by measuring an absolute value of the height that changes within a measurement region from the surface of an average height and taking the arithmetic average of such measurement values. The upper surface RB and the side surface of the wiring layer 20C are roughened by the roughening processing, and microscopic concavities and convexities are formed on such surfaces. The roughening processing is performed to enhance the adhesiveness of the insulating layer 33 with respect to the wiring layer 20C in the next step illustrated in FIG. 3E. The roughening processing may be performed, for example, by etching processing, CZ processing, blackening processing (oxidation treatment), sandblast processing, and the like.

Subsequently, in the step illustrated in FIG. 3E, the insulating layer 33 that covers the wiring layer 20C is stacked on the upper surface 32B of the insulating layer 32. Furthermore, a metal foil 66 is stacked on the upper surface 33B of the insulating layer 33. The metal foil 66 serves as the metal foil 23 (see FIG. 1A) of the wiring layer 20D. The metal foil 66 is formed to be thinner than the wiring layer 20C. Copper and copper alloy, for example, may be used for the material of the metal foil 66. First, for example, a prepreg in a half-cured state obtained by impregnating the thermosetting insulating resin such as epoxy resin in a reinforcement material such as glass cloth is prepared. The prepreg and the metal foil 66 are sequentially stacked on the upper surface 32B of the insulating layer 32 of the structure illustrated in FIG. 3D. The stacked body illustrated in FIG. 3E is then pressurized from above and below at a temperature of about 190° C. to 200° C. in a vacuum atmosphere. Thus, the wiring layer 20C is press-fitted into the prepreg. Furthermore, the insulating layer 33 made from an insulating resin containing the reinforcement material such as glass epoxy resin and the like is obtained when the prepreg is cured. The wiring layer 20C is adhered to the insulating layer 33 and the metal foil 66 is adhered to the upper surface 33B of the insulating layer 33 with the curing of the prepreg.

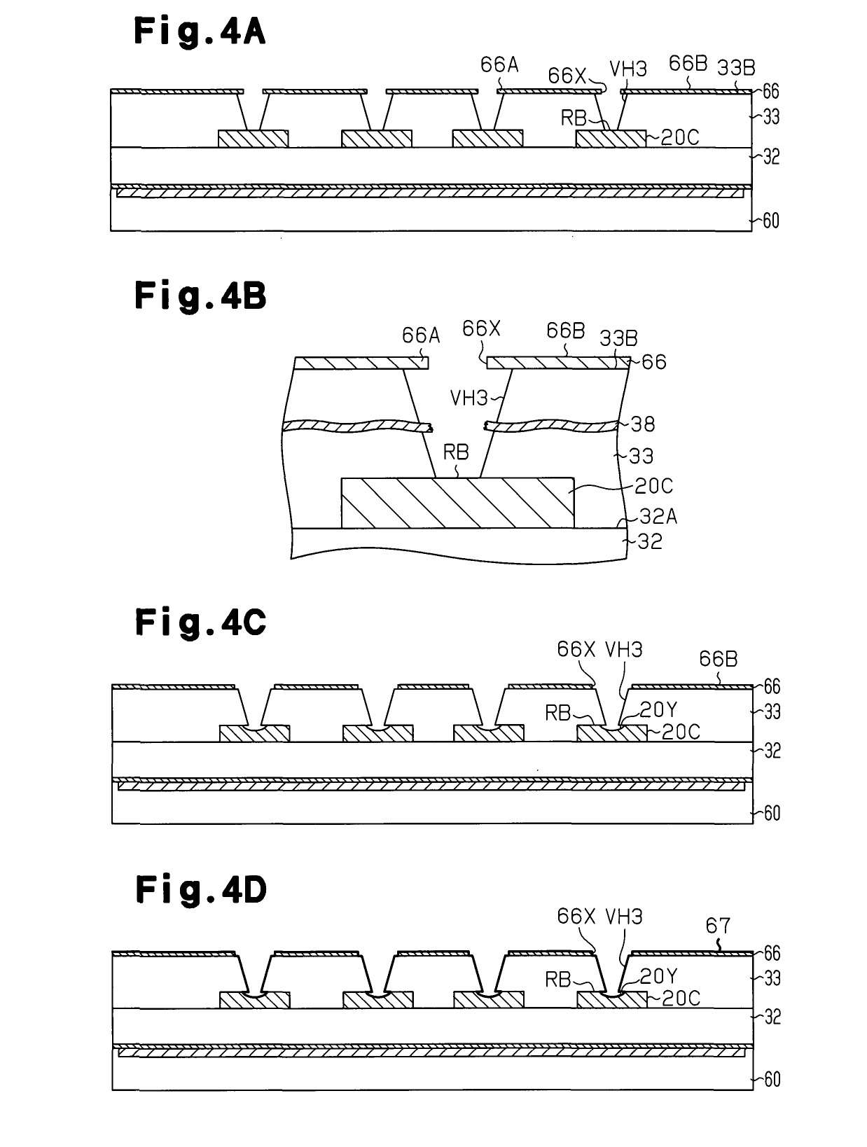

The pre-processing of laser processing is then performed on the metal foil 66. In this step, for example, the roughening processing, blackening processing, or the like is performed on the metal foil 66. According to such processing, the metal foil 66 tends to easily absorb laser light when the metal foil 66 is irradiated with laser light in the next step illustrated in FIG. 4A so that hole drilling may be efficiently carried out.

In the step illustrated in FIG. 4A, an opening 66X is formed in the metal foil 66 and the through hole VH3 is formed in the insulating layer 33 using the laser processing method by CO₂ laser, UV-YAG laser, and the like. The through hole VH3 communicates with the opening 66X, and extends through the insulating layer 33 in the thickness direction to expose the upper surface RB (first surface) of the wiring layer 20C. In this case, the through hole VH3 of the insulating layer 33 is formed to bite into the lower side of the metal foil 66 from the opening 66X, as illustrated in FIG. 4A, due to the fast advancement of the laser processing in the insulating layer 33 than the metal foil 66 (copper foil) and the influence of the laser heat. In other words, a structure or a so-called overhang structure in which a collar portion 66A of the metal foil 66 having a ring shape projecting to the inner side of the through hole VH3 is formed at the upper part of the through hole VH3. When the through hole VH3 is formed by laser processing, the end of the glass cloth 38 cut by laser projects to the inner side from the inner wall of the through hole VH3, as illustrated in FIG. 4B.

In the step illustrated in FIG. 4C, the post-processing of laser processing is performed on the structure illustrated in FIG. 4A. In this step, the etching processing is performed on the structure illustrated in FIG. 4A to remove the overhang structure (collar portion 66A) and to form the recess 20Y in the upper surface RB of the wiring layer 20C. In the present example, the etching processing is performed so that the opening diameter of the opening 66X of the metal foil 66 is larger than the open end on the upper side of the through hole VH3 and so that the opening diameter of the recess 20Y is larger than the open end on the lower side of the through hole VH3. For example, a resist layer (not illustrated) exposing only the metal foil 66 of the region to be removed is formed on the upper surface 66B of the metal foil 66, and the metal foil 66 and the wiring layer 20C are etched using the resist layer as the etching mask. Since the wiring layer 20C is thicker than the metal foil 66, the wiring layer 20C is suppressed from being passed through by etching even if the etching amount in this step is increased. Therefore, the overhang structure (collar portion 66A) may be suitably removed by increasing the etching amount in this step. The etching processing of this step may be performed by wet etching, for example. If the wet etching is performed on the wiring layer 20C, a side etch phenomenon in which the etching advances in the in-plane direction of the wiring layer 20C occurs. The recess 20Y of the wiring layer 20C then extends to the outer side from the bottom of the through hole VH3.

The resin smear (resin residual) in the through hole VH3 is then removed through desmear processing. The desmear processing may be performed using, for example, permanganate process. In the step illustrated in FIG. 4D, a seed layer 67 is formed to cover the inner surfaces of the through hole VH3 and the recess 20Y and the respective exposed surfaces of the insulating layer 33 and the metal foil 66. The seed layer 67 may be formed by non-electrolytic plating, for example. Copper or copper alloy, for example, may be used as the material of the seed layer 67.

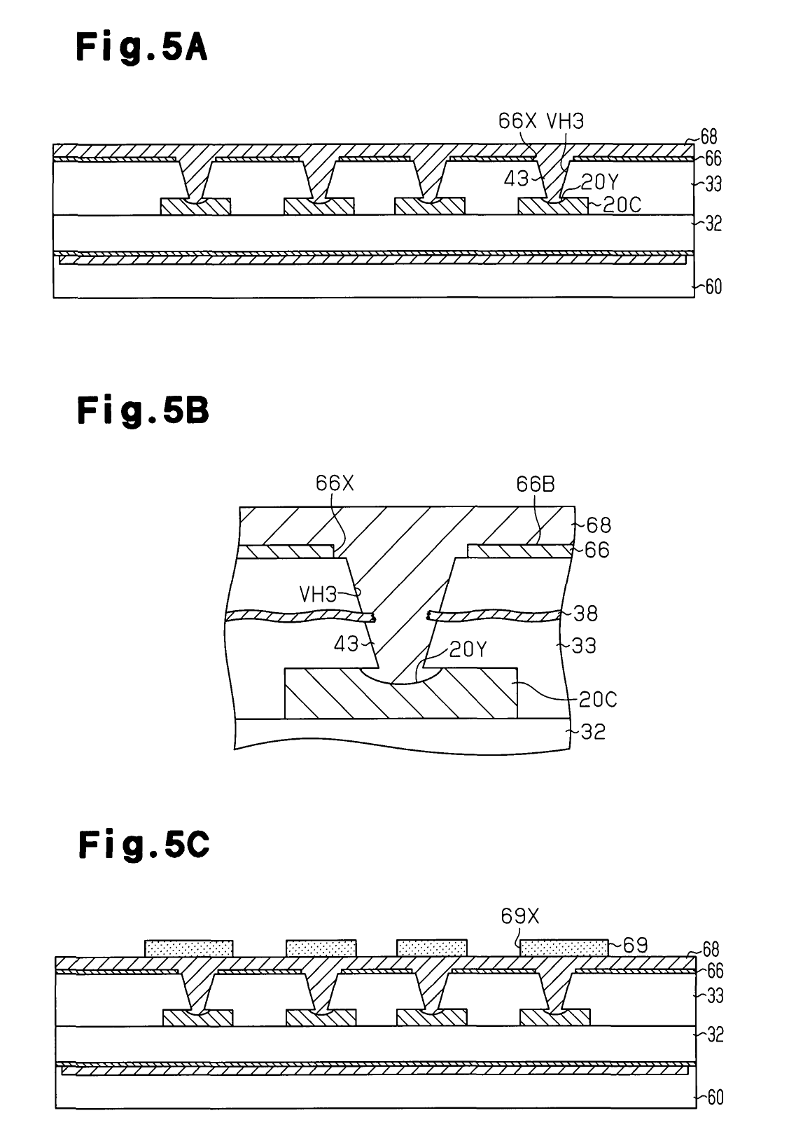

As illustrated in FIG. 5A, the electrolytic plating is performed using the seed layer 67 as the plating power supply layer to form the via 43 for filling the through hole VH3 and the recess 20Y, and a conductive layer 68 for covering the via 43 and the metal foil 66. In this case, the via 43 filled in the through hole VH3 covers the entire surface of the end of the glass cloth 38 projecting to the inner side from the inner wall of the through hole VH3, as illustrated in FIG. 5B. In other words, the end of the glass cloth 38 projects into the via 43. The tensile strength of the via 43 thus becomes high, and the connection reliability of the via 43 and the insulating layer 33 may be enhanced.

In the step illustrated in FIG. 5C, a resist layer 69 having an opening 69X at a given area is formed on an upper surface of the conductive layer 68. The resist layer 69 covers the conductive layer 68 and the metal foil 66 of a portion corresponding to the wiring layer 20D illustrated in FIG. 1A. In view of the etching processing of the next step, a material having etching resistance property may be used for the material of the resist layer 69. For example, the material in the same manner as the resist layer 65 may be used for the material of the resist layer 69.

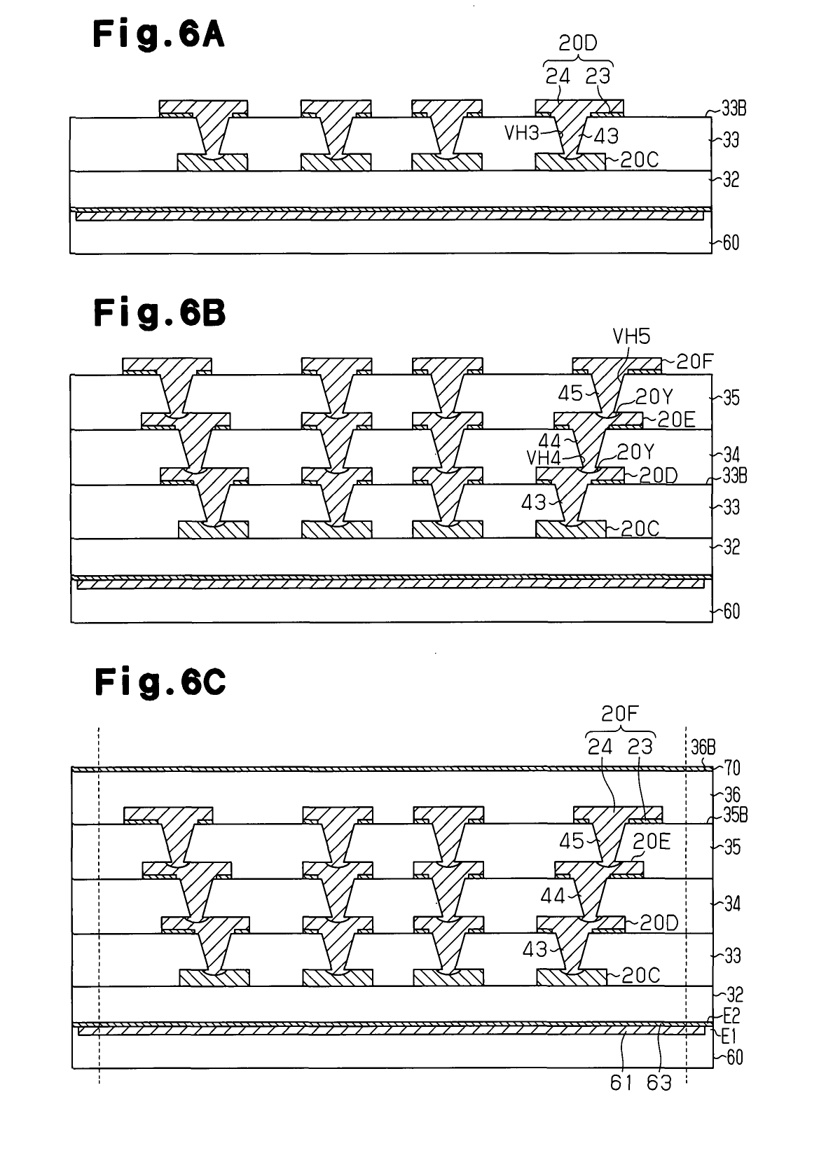

The conductive layer 68 and the metal foil 66 exposed from the opening 69X of the resist layer 69 are then etched using the resist layer 69 as an etching mask to pattern the conductive layer 68 and the metal foil 66 to a given shape. As a result, as illustrated in FIG. 6A, the wiring layer 20D including the metal foil 23 and the wiring pattern 24 is formed on the upper surface 33B of the insulating layer 33. The wiring layer 20D and the wiring layer 20C are thus electrically connected by the via 43. Thus, in the present example, the via 43 and the wiring layer 20D are formed through the subtractive method. The method for forming the via 43 and the wiring layer 20D is not limited to the subtractive method, and other wiring forming methods such as semi-additive method, and the like may also be adopted.

The steps illustrated in FIG. 3E to FIG. 6A are then repeated. As a result, as illustrated in FIG. 6B, the insulating layers 34, 35 and the wiring layers 20E, 20F are alternately stacked on the upper surface 33B of the insulating layer 33. Furthermore, the through holes VH4, VH5 extending through the insulating layers 34, 35 in the thickness direction, and the vias 44, 45 are formed. In this case, the recess 20Y that communicates with the through hole VH4 and has a diameter larger than the opening diameter of the bottom of the through hole VH4 is formed in the upper surface of the wiring layer 20D. The via 44 is then filled in the through hole VH4 and the recess 20Y. In the same manner, the recess 20Y that communicates with the through hole VH5 and has a diameter larger than the opening diameter of the bottom of the through hole VH5 is formed in the upper surface of the wiring layer 20E. The via 45 is then filled in the through hole VH5 and the recess 20Y.

In the step illustrated in FIG. 6C, a manufacturing step similar to the step illustrated in FIG. 3E is repeated. As a result, the insulating layer 36 that covers the wiring layer 20F is stacked on the upper surface 35B of the insulating layer 35. Furthermore, a metal foil 70 is stacked on the upper surface 36B of the insulating layer 36. The thickness from the upper surface of the wiring pattern 24 of the wiring layer 20F to the upper surface 36B of the insulating layer 36 is set to the same thickness as the insulating layer 32. The metal foil 70 serving as the metal foil 23 (see FIG. 1A) of the wiring layer 20G is set to the same thickness as the metal foil 63.

The structure illustrated in FIG. 6C is then cut at a position (position indicated with a broken line in FIG. 6C) corresponding to the edge of the underlayer 61. The cutting position is set slightly on the inner side than the edge of the underlayer 61 to remove the edges E1, E2 of the support body 60 and the metal foil 63 connected to each other. Furthermore, the cutting position is set so that the edges E1, E2 do not remain in view of the position accuracy of a router used to cut the structure illustrated in FIG. 6C, for example. The structure merely needs to be cut so that the edges E1, E2 do not remain, and for example, the structure may be cut by moving the router along the edge of the underlayer 61 according to the size (thickness) of the router bit.

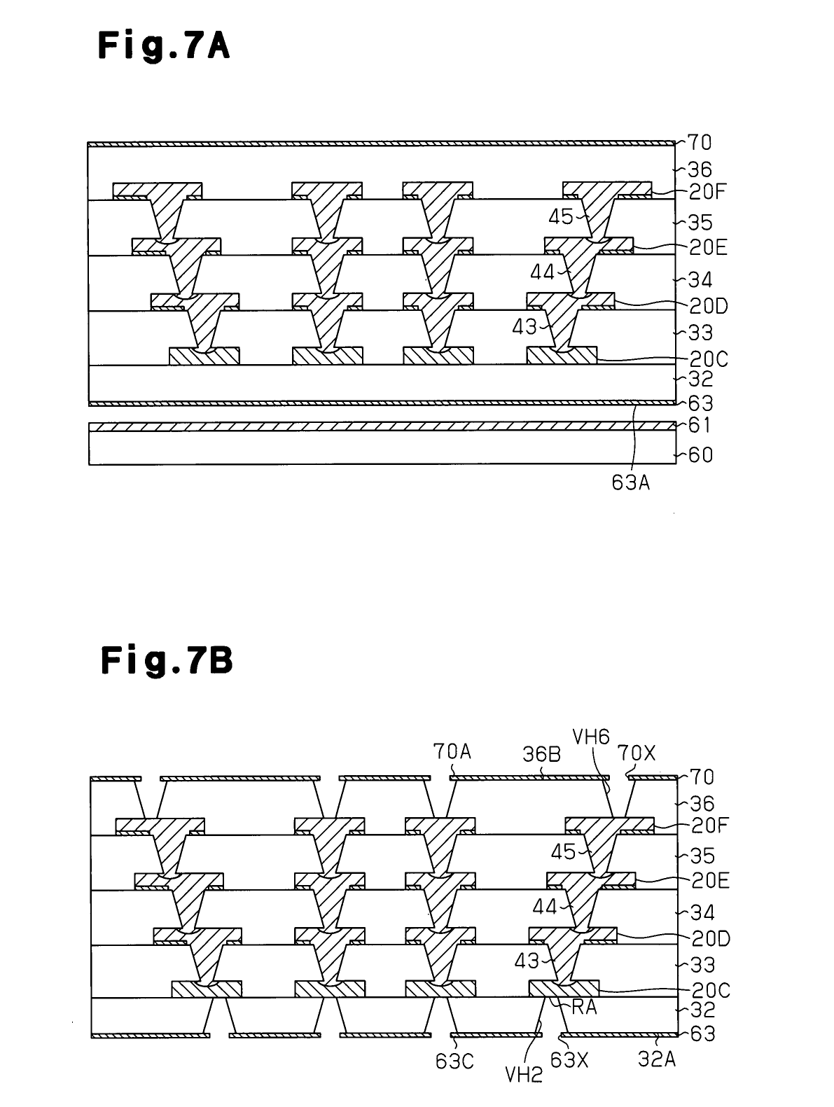

After the edges E1, E2 are cut, the underlayer 61 and the metal foil 63 are merely in a contacted state. Thus, the underlayer 61 and the metal foil 63 may be easily separated, as illustrated in FIG. 7A. A structure in which the insulating layer 36 that covers the wiring layer 20F and the metal foil 70 are sequentially stacked on the insulating layer 35, and the insulating layer 32 that covers the wiring layer 20C and the metal foil 63 sequentially stacked on the lower surface 33A of the insulating layer 33 is thus obtained. In this case, the lower surface 63A of the metal foil 63 contacting the underlayer 61 is shaped to lie along the upper surface (flat surface) of the underlayer 61. In other words, the shape of the upper surface of the underlayer 61 is transferred onto the lower surface 63A of the metal foil 63. Furthermore, since the metal foil 63 is supported by the support body 60 having high mechanical strength until the previous step, the lower surface 63A of the metal foil 63 is flatter than the upper surface of the metal foil 70 on the opposite side.

A manufacturing step similar to the step of FIG. 4A is then performed on the insulating layers 36, 32 and the metal foils 70, 63 formed in the structure illustrated in FIG. 7A. More specifically, the opening 63X is formed in the metal foil 63, and the through hole VH2 that communicates with the opening 63X and extends through the insulating layer 32 in the thickness direction to expose the lower surface RA (second surface) of the wiring layer 20C is formed by the laser processing method. Furthermore, the opening 70X is formed in the metal foil 70, and the through hole VH6 that communicates with the opening 70X and extends through the insulating layer 36 in the thickness direction to expose the upper surface of the wiring layer 20F is formed by the laser processing method. In this case, the collar portion 63C of the metal foil 63 projects to the inner side of the through hole VH2 at the lower part of the through hole VH2, and the collar portion 70A of the metal foil 70 projects to the inner side of the through hole VH6 at the upper part of the through hole VH6.

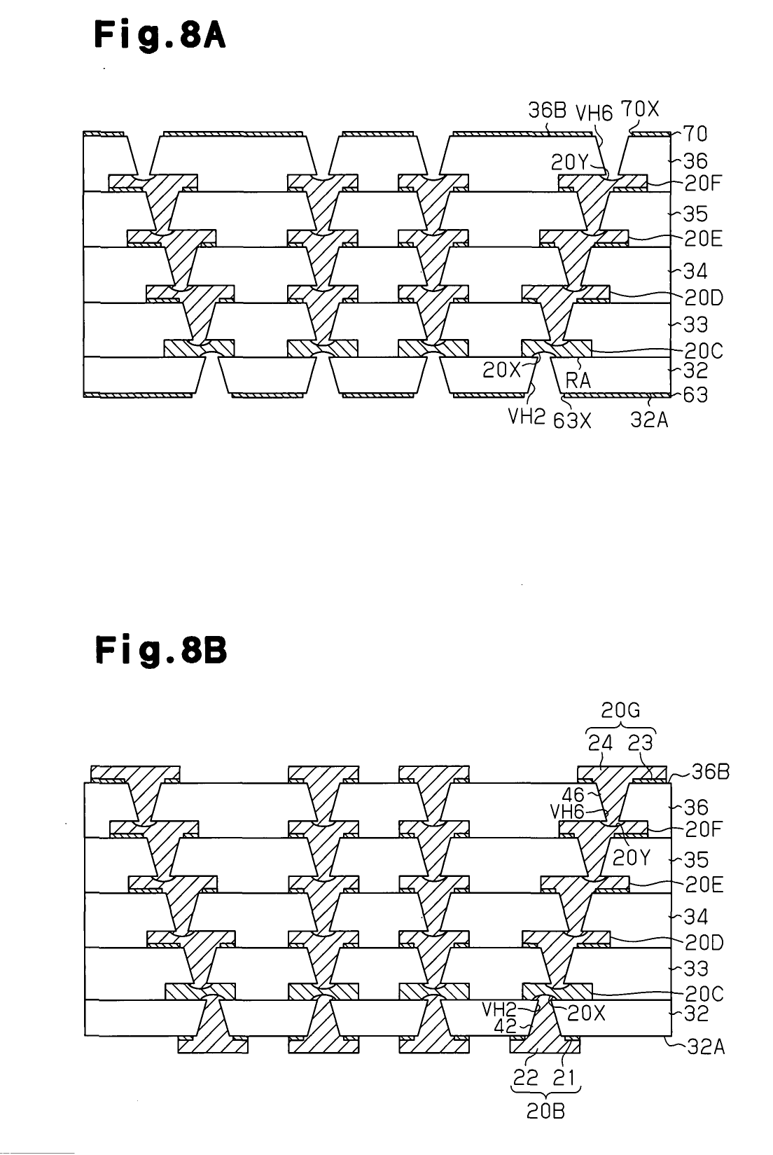

A manufacturing step similar to the step illustrated in FIG. 4C is then performed on the structure illustrated in FIG. 7B. According to such step, the metal foil 63 is etched so that the opening diameter of the opening 63X of the metal foil 63 is larger than the open end on the lower side of the through hole VH2, as illustrated in FIG. 8A. Furthermore, the recess 20X having a diameter larger than the open end on the upper side of the through hole VH2 is formed in the lower surface RA of the wiring layer 20C. Since the wiring layer 20C is thicker than the metal foil 63, the collar portion 63C of the metal foil 63 may be suitably removed even if the etching amount is increased. In this step, the metal foil 70 is etched so that the opening diameter of the opening 70X of the metal foil 70 is larger than the open end on the upper side of the through hole VH6, and the recess 20Y having a diameter larger than the open end on the lower side of the through hole VH6 is formed in the upper surface of the wiring layer 20F.

As described above, the thickness from the lower surface 32A of the insulating layer 32 to the lower surface RA of the wiring layer 20C is set to the same thickness as the thickness from the upper surface 36B of the insulating layer 36 to the upper surface of the wiring layer 20F. The metal foil 63 and the metal foil 70 are set to the same thickness. Thus, in the steps illustrated in FIG. 7B and FIG. 8A, the etching amount in forming the through hole VH2 and the recess 20X may be set to the same value as the etching amount in forming the through hole VH6 and the recess 20Y.

Then, manufacturing steps similar to the steps illustrated in FIGS. 4D to 6A are performed on the structure illustrated in FIG. 8A. According to such steps, the via 42 is filled in the through hole VH2 and the recess 20X, and the via 46 is filled in the through hole VH6 and the recess 20Y, as illustrated in FIG. 8B. The metal foil 63 is patterned to form the metal foil 21. As a result, the wiring layer 20B including the metal foil 21 and the wiring pattern 22 is stacked on the lower surface 32A of the insulating layer 32. Furthermore, the metal foil 70 is patterned to form the metal foil 23. As a result, the wiring layer 20G including the metal foil 23 and the wiring pattern 24 is stacked on the upper surface 36B of the insulating layer 36.

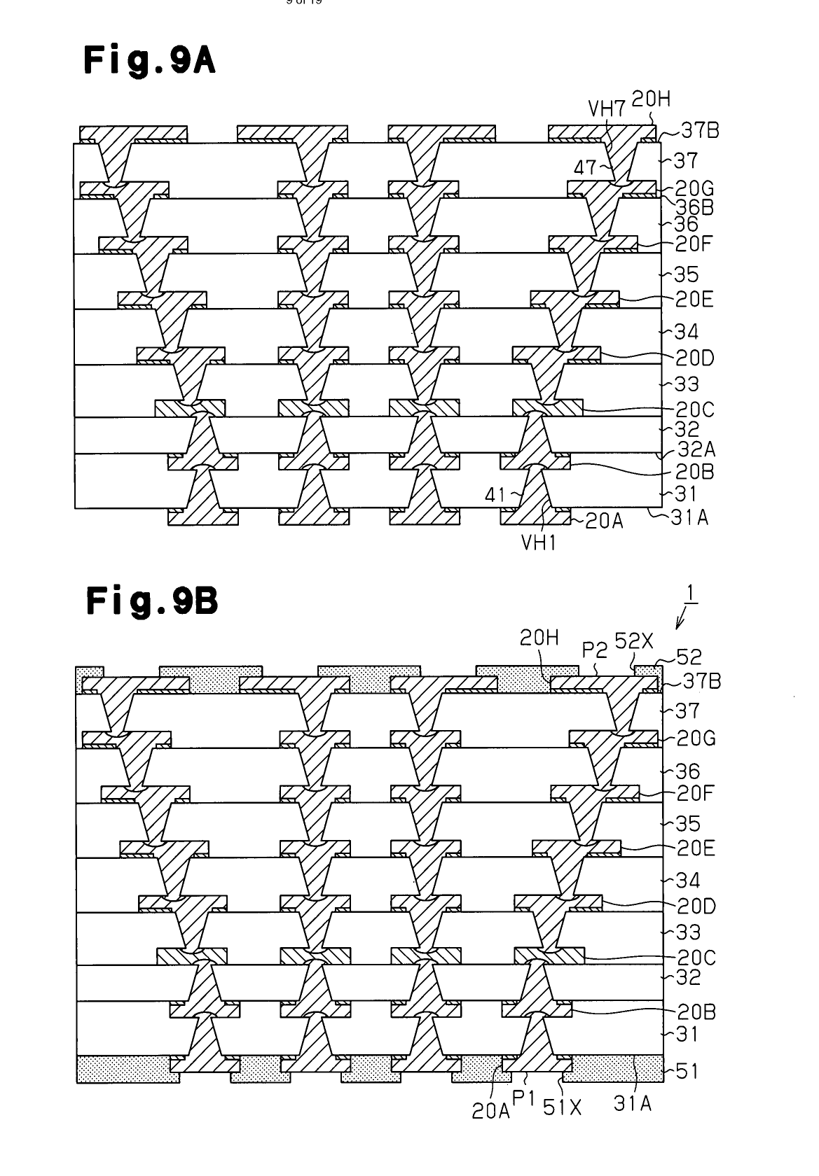

Manufacturing steps similar to the steps illustrated in FIGS. 3E to 6A are then performed on the structure illustrated in FIG. 8B. According to such steps, the insulating layer 37 and the wiring layer 20H are sequentially stacked on the upper surface 36B of the insulating layer 36, and the insulating layer 31 and the wiring layer 20A are sequentially stacked on the lower surface 32A of the insulating layer 32, as illustrated in FIG. 9A.

In the step illustrated in FIG. 9B, the solder resist layer 51, which has the opening 51X for exposing the wiring layer 20A as the pad P1 at a given area, is stacked on the lower surface 31A of the insulating layer 31. The solder resist layer 52, which has the opening 52X for exposing the wiring layer 20H as the external connection pad P2 at a given area, is stacked on the upper surface 37B of the insulating layer 37. The solder resist layers 51, 52 may be formed by laminating the photosensitive solder resist film (or applying liquid solder resist), for example, and patterning the resist to a given shape. Part of the wiring layer 20A is thus exposed from the opening 51X of the solder resist layer 51 as the pad P1, and part of the wiring layer 20H is exposed from the opening 52X of the solder resist layer 52 as the external connection pad P2. A metal layer in which the Ni layer and the Au layer are sequentially stacked, for example, may be formed on the pad P1 and the external connection pad P2, when necessary. The metal layer may be formed through non-electrolytic plating, for example. The wiring substrate 1 illustrated in FIG. 1 may be manufactured according to the manufacturing steps described above.

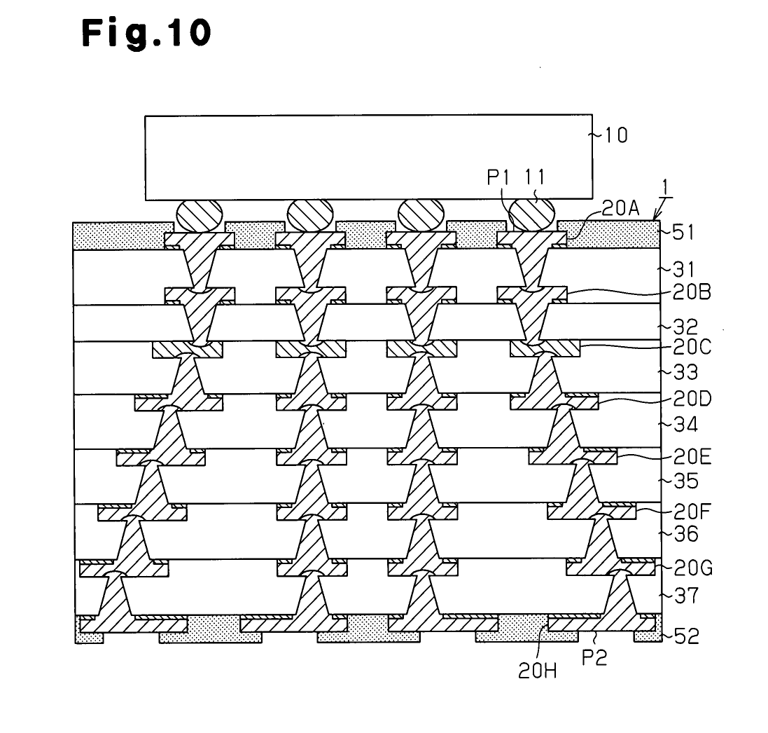

In the step illustrated in FIG. 10, the semiconductor chip 10 is first mounted on the wiring substrate 1 manufactured as above. In other words, the bump 11 of the semiconductor chip 10 is flip-chip joined on the pad P1 of the wiring substrate 1. The underfill resin 13 (see FIG. 2) is then filled between the wiring substrate 1 and the semiconductor chip 10, which are flip-chip joined, and the underfill resin 13 is cured. The semiconductor device 2 illustrated in FIG. 2 may be manufactured according to such manufacturing steps.

The first embodiment has the advantages described below.

(1) The opening diameter Φ2 of the opening 21X of the metal foil 21 is set to be wider than the opening diameter Φ1 of the open end on the lower side of the through hole VH2. Furthermore, the opening diameter Φ6 of the opening 23X of the metal foil 23 is set to be wider than the opening diameter Φ5 of the open end on the upper side of the through hole VH3. Thus, when forming the vias 42, 43 in the through holes VH2, VH3 through the electrolytic plating, the plating is suppressed from depositing from near the openings 21X, 23X of the metal foils 21, 23. The void is thus suppressed from forming inside the vias 42, 43.

(2) The overhang structure (e.g., collar portion 92A illustrated in FIG. 19B) may be also removed by increasing the etching amount when removing the overhang structure in the conventional manufacturing method. However, a through hole may form in the copper foil 91 (see FIG. 19B) if the etching amount is increased. If the electrolytic plating is performed with the through hole formed in the copper foil 91, the filling property of the plated layer (conductive layer) degrades. A recess thus may form at the surface of the filled via 94 (see FIG. 19D).

In the first embodiment, however, the wiring layer 20C is formed to be thicker than, for example, the metal foil 66 (metal foil 23) and the metal foil 63 (metal foil 21). Thus, even when removing the overhang structure (e.g., collar portion 66A illustrated in FIG. 4B) by increasing the etching amount, a through hole is suitably suppressed from being formed in the wiring layer 20C by the etching. This overcomes the problem of the prior art.

(3) If the conventional copper foil 91 (see FIG. 19A) is simply formed to be thick, warping tends to occur at the core material 90. In the first embodiment, however, various manufacturing steps (laser processing, etching processing, etc.) are performed with the wiring layer 20C, the insulating layer 32, and the like supported by the support body 60 having high mechanical strength. Thus, warping is suitably suppressed from occurring in the structure of the manufacturing process even if the wiring layer 20C is formed to be thicker than the metal foil 66, and the like.

(4) The wiring layer 20C is configured by only one metal layer. The adhesiveness and the connection reliability of the vias 42, 43 and the wiring layer 20C are thus enhanced.

(5) The via 42 joined to the lower surface RA of the wiring layer 20C is filled in the through hole VH2 and the recess 20X, which has a diameter larger than the opening diameter Φ3 of the opening at the upper end of the through hole VH2. The via 43 joined to the upper surface RB of the wiring layer 20C is filled in the through hole VH3 and the recess 20Y, which has a diameter larger than the opening diameter Φ7 of the opening at the lower end of the through hole VH3. The adhesiveness of the via 42 and the insulating layer 32, and the adhesiveness of the via 43 and the insulating layer 33 are thus enhanced.

(6) The end B1 of the via 42 on the lower side and the end B2 of the via 43 on the upper side are joined to one wiring layer 20C. The entire wiring substrate 1 is thus thin.

(7) Each via 41 to 47 covers the entire surface of the end of the glass cloth 38 projecting to the inner side from the inner wall of the corresponding through hole VH1 to VH7. In other words, the end of the glass cloth 38 projects into the via 41 to 47. The tensile strength of the vias 41 to 47 thus becomes high, and the connection reliability of the vias 41 to 47 and the insulating layers 31 to 37 is enhanced.

(8) The wiring layer 20C, the insulating layer 33, the wiring layer 20D, the insulating layer 34, the wiring layer 20E, the insulating layer 35, the wiring layer 20F, and the insulating layer 36 are sequentially stacked on the upper surface 32B of the insulating layer 32, and then the support body 60 is removed. Then, the wiring layers 20A, 20B, 20G, 20H and the insulating layers 31, 32, 37 are stacked. According to such method, the shape of the upper surface (flat surface) of the support body 60 (underlayer 61) is transferred to the metal foil 63 and the insulating layer 32 when the support body 60 is removed. The insulating layer 32 is thus flatter than the insulating layer 36 on the opposite side. Accordingly, the insulating layer 31 (the outermost insulating layer 31) located at the lower side than the insulating layer 32 is flatter than the outermost insulating layer 37 on the opposite side in the completed wiring substrate 1. Therefore, the semiconductor chip 10 is easily flip-chip joined to the wiring layer 20F (pad P1) stacked on the insulating layer 32.

(9) The through holes VH2, VH3 are formed so that the diameter becomes smaller toward the wiring layer 20C. The acceptable amount with respect to the position shift of the through holes VH2, VH3 is thus increased.

(10) The insulating layers 31 to 37 of the wiring substrate 1 are all made from an insulating resin containing the reinforcement material. Therefore, the insulating layers 31 to 37 all have high mechanical strength. Warping of the wiring substrate 1 is thus effectively reduced.

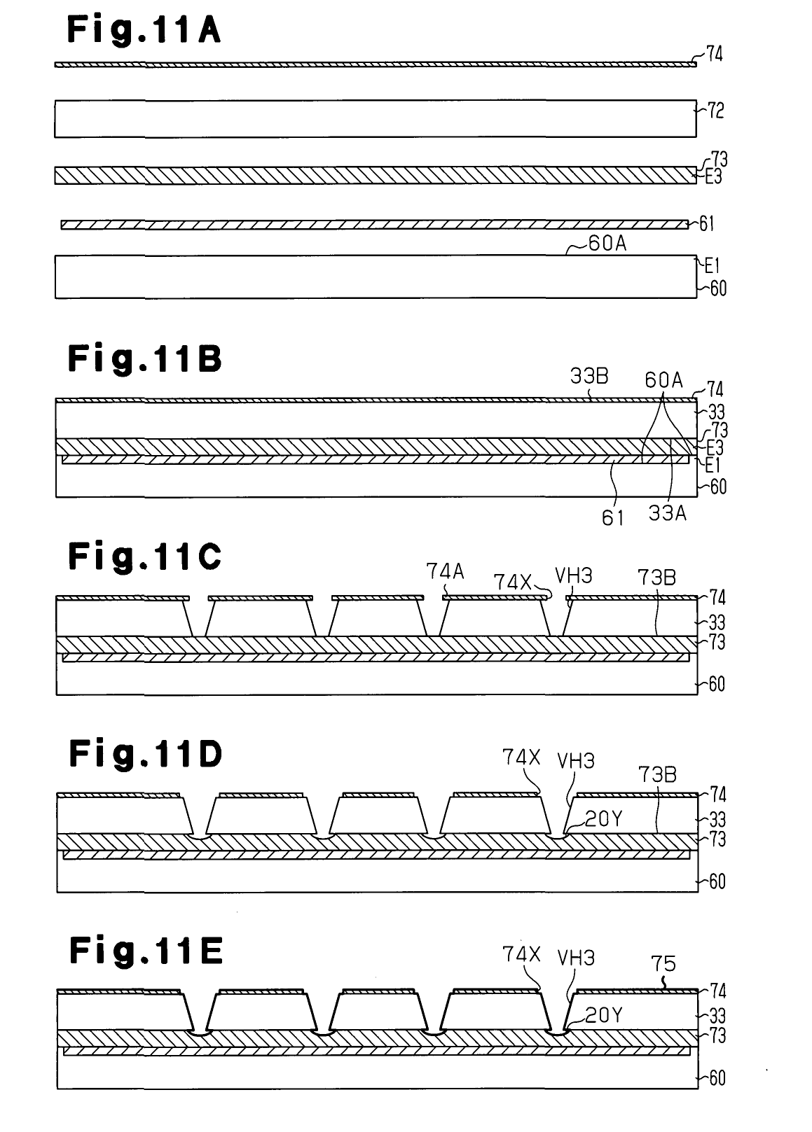

A second embodiment will now be described with reference to FIGS. 11A to 16B. The second embodiment differs from the first embodiment in the manufacturing method. The description will focus on differences from the first embodiment.

As illustrated in FIG. 11A, the support body 60, the underlayer 61, a metal foil 73, an insulating layer 72, and a metal foil 74 are first prepared.

The insulating layer 72 serving as the insulating layer 33 is a prepreg in a half-cured state obtained by impregnating the thermosetting insulating resin such as epoxy resin, polyimide resin, and the like in a reinforcement material such as glass cloth, glass non-woven cloth, aramid woven cloth, and the like.

The metal foil 73, which is the base material of the wiring layer 20C, is formed to be thicker than the metal foil 74, which is the base material of the metal foil 23 of the wiring layer 20D. Copper and copper alloy, for example, may be used for the material of the metal foils 73, 74.

The insulating layer 72 and the metal foils 73, 74 are set to the same size as the support body 60. Thus, the edge of the insulating layer 72, the edge E3 of the metal foil 73, and the edge of the metal foil 74 project from each side of the underlayer 61 toward the outer side, in the same manner as the edge E1 of the support body 60.

The underlayer 61, the metal foil 73, the insulating layer 72, and the metal foil 74 are sequentially stacked from the support body 60 on an upper surface 60A (first surface) of the support body 60. The edge E3 of the metal foil 73 and the edge E1 of the support body 60 thus face each other. Subsequently, the stacked body of the support body 60, the underlayer 61, the metal foil 73, the insulating layer 72, and the metal foil 74 are pressurized from above and below at a temperature of about 190° C. to 200° C. in a depressurized environment (e.g., vacuum atmosphere). As illustrated in FIG. 11B, the insulating layer 72 is thus cured, and the insulating layer 33 made from an insulating resin containing the reinforcement material such as glass epoxy resin, and the like, is obtained. In this case, the underlayer 61 and the metal foil 73 are merely in contact in a superimposed region of the underlayer 61 and the metal foil 73. Thus, the underlayer 61 and the metal foil 73 may be easily separated in the superimposed region.

The pre-processing of laser processing is then performed on the metal foil 74. In this step, for example, the roughening processing, blackening processing, and the like are performed on the metal foil 74.

In the step illustrated in FIG. 11C, an opening 74X is formed in the metal foil 74 and the through hole VH3 that communicates with the opening 74X, and extends through the insulating layer 33 to expose the upper surface 73B (first surface) of the metal foil 73 is formed using the laser processing method by CO₂ laser, UV-YAG laser, and the like. In this case, a structure or a so-called overhang structure in which a collar portion 74A of the metal foil 74 having a ring shape projecting to the inner side of the through hole VH3 is formed at the upper part of the through hole VH3, as illustrated in FIG. 11C.

In the step illustrated in FIG. 11D, the etching processing is performed on the structure illustrated in FIG. 11C according to a manufacturing step similar to the step illustrated in FIG. 4C. The overhang structure (collar portion 74A) is thus removed, and the recess 20Y extending to the outer side from the bottom of the through hole VH3 forms in the upper surface 73B (first surface) of the metal foil 73.

The resin smear (resin residual) in the through hole VH3 is then removed through the desmear processing. In the step illustrated in FIG. 11E, a seed layer 75 is formed to cover the inner surfaces of the through hole VH3 and the recess 20Y and the respective exposed surfaces of the insulating layer 33 and the metal foil 74.

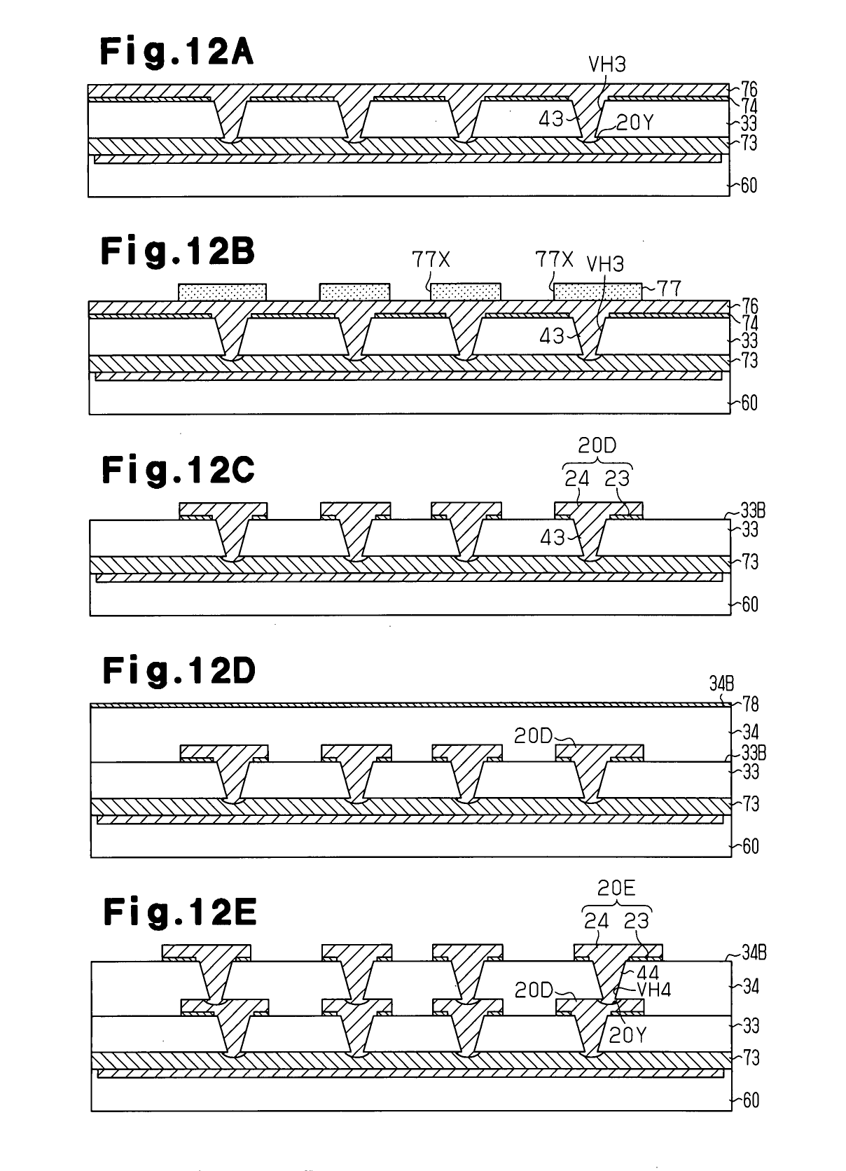

Electrolytic plating is then performed using the seed layer 75 as the plating power supply layer. As illustrated in FIG. 12A, the via 43 is thus filled in the through hole VH3 and the recess 20Y, and a conductive layer 76 that covers the via 43 and the metal foil 74 is formed.

In the step illustrated in FIG. 12B, a resist layer 77 having an opening 77X at a given area is formed on an upper surface of the conductive layer 76. The resist layer 77 covers the conductive layer 76 and the metal foil 74 of a portion corresponding to the wiring layer 20D (see FIG. 1A). In view of the etching processing of the next step, a material having etching resistance property may be used for the material of the resist layer 77. For example, the material in the same manner as the resist layer 65 may be used as the material of the resist layer 77.

The conductive layer 76 and the metal foil 74 exposed from the opening 77X of the resist layer 77 are then etched using the resist layer 77 as an etching mask to pattern the conductive layer 76 and the metal foil 74 to a given shape. As a result, as illustrated in FIG. 12C, the wiring layer 20D including the metal foil 23 and the wiring pattern 24 is formed on the upper surface 33B (first surface) of the insulating layer 33. The wiring layer 20D and the metal foil 73 are thus electrically connected by the via 43. Thus, in the present example, the via 43 and the wiring layer 20D are formed through the subtractive method. The method for forming the via 43 and the wiring layer 20D is not limited to the subtractive method, and other wiring forming methods such as semi-additive method, and the like may also be adopted.

The resist layer 77 illustrated in FIG. 12B is then removed with an alkaline stripping solution, for example. The roughening processing of the wiring layer 20D is then performed. The roughening processing is performed, for example, so that the roughness degree of the upper surface and the side surface of the wiring layer 20D becomes about 0.5 to 2 μm in a surface roughness value Ra.

In the step illustrated in FIG. 12D, a manufacturing step similar to the step illustrated in FIG. 3E is performed. According to this step, the insulating layer 34 for covering the wiring layer 20D is stacked on the upper surface 33B of the insulating layer 33, and a metal foil 78 is stacked on the upper surface 34B of the insulating layer 34. The metal foil 78 used as the metal foil 23 (see FIG. 1A) of the wiring layer 20E is formed to be thinner than the metal foil 73.

Manufacturing steps similar to the steps illustrated in FIG. 11B to FIG. 12C are then performed on the structure illustrated in FIG. 12D. According to such steps, the through hole VH4 is formed in the insulating layer 34, and the recess 20Y that communicates with the through hole VH4 and has a diameter larger than the opening diameter of the bottom of the through hole VH4 is formed in the upper surface of the wiring layer 20D. The via 44 is then filled in the through hole VH4 and the recess 20Y. Furthermore, the wiring layer 20E electrically connected to the via 44 is stacked on the upper surface 34B of the insulating layer 34.

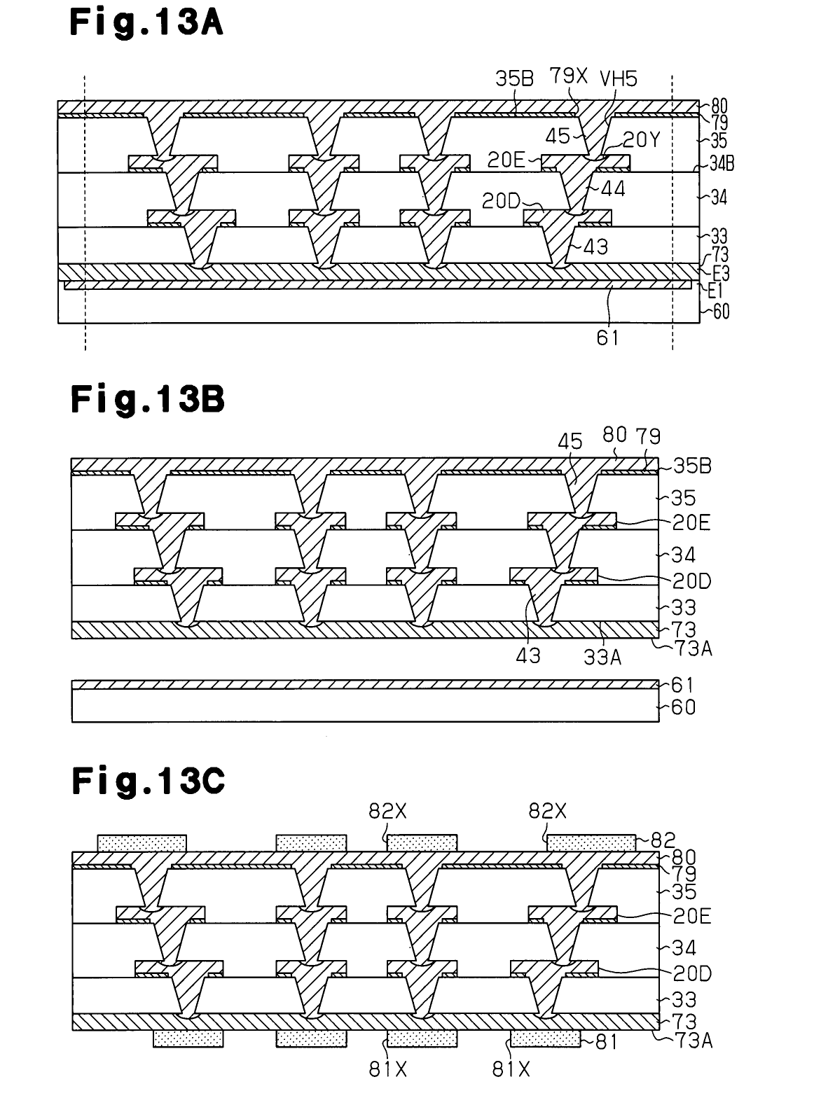

A manufacturing step similar to the step illustrated in FIG. 12D is then performed on the structure illustrated in FIG. 12E. Then, manufacturing steps similar to the steps illustrated in FIG. 11C to FIG. 12A are performed. According to such steps, the insulating layer 35 is stacked on the upper surface 34B of the insulating layer 34, and the through hole VH5 is formed in the insulating layer 35, as illustrated in FIG. 13A. The recess 20Y that communicates with the through hole VH5 and has a diameter larger than the opening diameter of the bottom of the through hole VH5 is formed in the upper surface (first surface) of the wiring layer 20E. The via 45 is then filled in the through hole VH5 and the recess 20Y. Furthermore, a conductive layer 80 that is stacked on the upper surface 35B of the insulating layer 35 to cover a metal foil 79 including an opening 79X and the via 45 is formed. In this case, the total thickness of the metal foil 79 and the conductive layer 80, that is, the thickness from the upper surface 35B of the insulating layer 35 to the upper surface of the conductive layer 80 is set to be the same thickness as the metal foil 73.

The structure illustrated in FIG. 13A is then cut at a position (position indicated with a broken line) corresponding to the edge of the underlayer 61. The cutting position is set slightly on the inner side than the edge of the underlayer 61 to remove the edges E1, E3 of the support body 60 and the metal foil 73 connected to each other.

When the edges E1, E3 are cut, the underlayer 61 and the metal foil 73 are merely in contacting with each other. Thus, the underlayer 61 and the metal foil 73 may be easily separated, as illustrated in FIG. 13B. A structure in which the conductive layer 80 that covers the entire upper surface 35B of the insulating layer 35 is stacked on the insulating layer 35, and the metal foil 73 that covers the entire lower surface 33A of the insulating layer 33 is stacked on the insulating layer 33 is thus obtained. In this case, the lower surface 73A of the metal foil 73 contacting the underlayer 61 is formed to a shape that lies along the upper surface (flat surface) of the underlayer 61. In other words, the shape of the upper surface of the underlayer 61 is transferred onto the lower surface 73A of the metal foil 73. Furthermore, since the metal foil 73 is supported by the support body 60 having high mechanical strength until the previous step, the lower surface 73A of the metal foil 73 is flatter than the upper surface of the metal foil 79 and the conductive layer 80 on the opposite side.

In the step illustrated in FIG. 13C, a resist layer 81 having an opening 81X at a given area is formed on the lower surface 73A of the metal foil 73. Furthermore, a resist layer 82 having an opening 82X at a given area is formed on the upper surface of the conductive layer 80. The resist layer 81 covers the metal foil 73 of a portion corresponding to the wiring layer 20C (see FIG. 1A). The resist layer 82 covers the conductive layer 80 and the metal foil 79 of a portion corresponding to the wiring layer 20F (see FIG. 1A). In view of the etching processing of the next step, a material having etching resistance property may be used for the material of the resist layers 81, 82. For example, the material in the same manner as the resist layer 65 may be used for the material of the resist layers 81, 82.

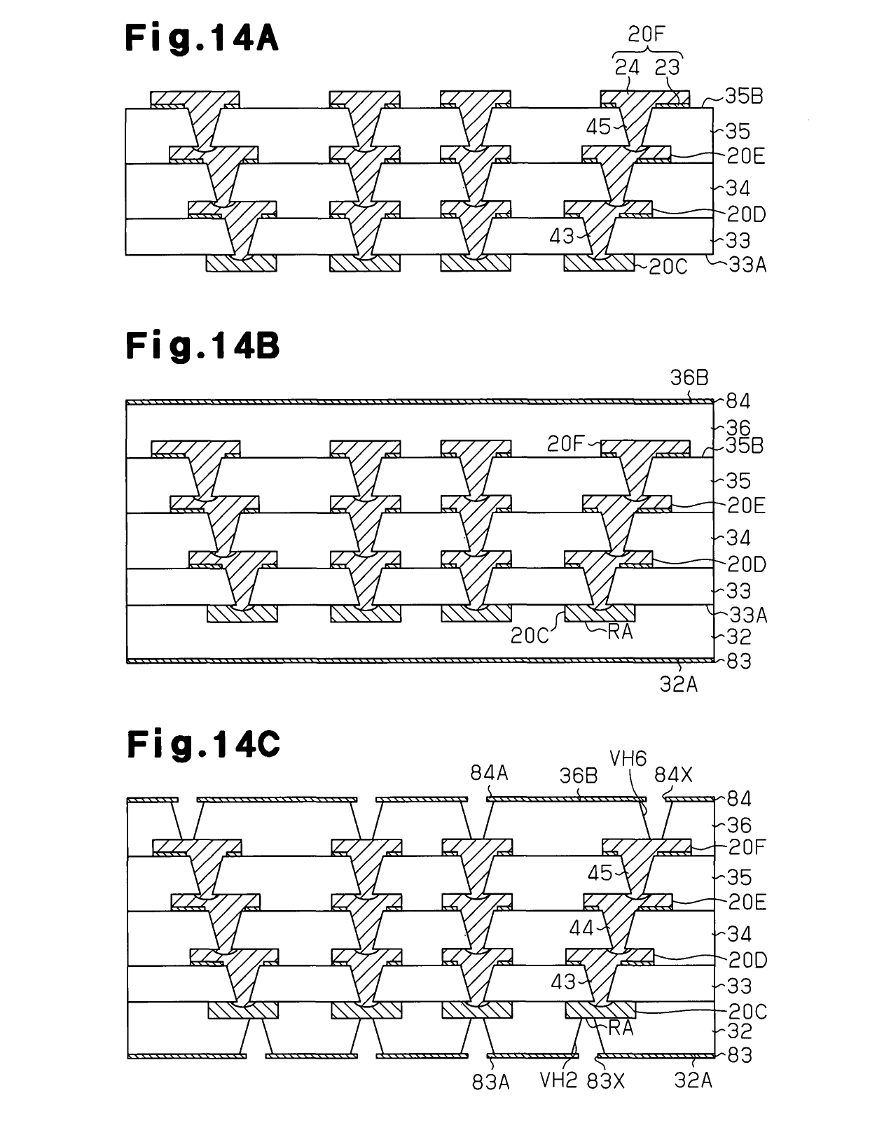

The metal foil 73 exposed from the opening 81X of the resist layer 81 is then etched using the resist layers 81, 82 as etching masks. Furthermore, the conductive layer 80 and the metal foil 79 exposed from the opening 82X of the resist layer 82 are etched. As a result, the metal foil 73, the conductive layer 80, and the metal foil 79 are patterned to certain shapes. In other words, as illustrated in FIG. 14A, the wiring layer 20C including one metal layer is formed on the lower surface 33A of the insulating layer 33, and the wiring layer 20C is electrically connected to the wiring layer 20D through the via 43. The wiring layer 20F including the metal foil 23 and the wiring pattern 24 is formed on the upper surface 35B of the insulating layer 35, and the wiring layer 20F is electrically connected to the wiring layer 20E through the via 45.

As described above, the total thickness of the metal foil 79 and the conductive layer 80 is set to the same thickness as the thickness of the metal foil 73. Thus, in the etching step of FIG. 13C, the etching amount of when patterning the metal foil 73 may be set to the same value as the etching amount of when patterning the metal foil 79 and the conductive layer 80.

A manufacturing step similar to the step illustrated in FIG. 12D is then performed on the structure illustrated in FIG. 14A. According to such a step, the insulating layer 32 that covers the lower surface RA and the side surface of the wiring layer 20C is stacked on the lower surface 33A (second surface) of the insulating layer 33, and the metal foil 83 is stacked on the lower surface 32A of the insulating layer 32, as illustrated in FIG. 14B. The metal foil 83 used as the metal foil 21 (see FIG. 1A) of the wiring layer 20B is formed thinner than the wiring layer 20C. The insulating layer 36 that covers the wiring layer 20F is stacked on the upper surface 35B of the insulating layer 35, and the metal foil 84 is stacked on the upper surface 36B of the insulating layer 36. In this case, the thicknesses of the insulating layers (insulating layers 32, 36 herein) stacked on the upper and lower surfaces of the structure are preferably set to the same thickness to suppress warping of the structure.

A manufacturing step similar to the step illustrated in FIG. 11C is then performed on the structure illustrated in FIG. 14B. In other words, the opening 83X is formed in the metal foil 83, and the through hole VH2 that communicates with the opening 83X and extends through the insulating layer 32 in the thickness direction to expose the lower surface RA of the wiring layer 20C is formed by the laser processing method. Furthermore, the opening 84X is formed in the metal foil 84, and the through hole VH6 that communicates with the opening 84X and extends through the insulating layer 36 in the thickness direction to expose the upper surface of the wiring layer 20F is formed by the laser processing method. In this case, the collar portion 83A of the metal foil 83 projects to the inner side of the through hole VH2 at the lower part of the through hole VH2, and the collar portion 84A of the metal foil 84 projects to the inner side of the through hole VH6 at the upper part of the through hole VH6.

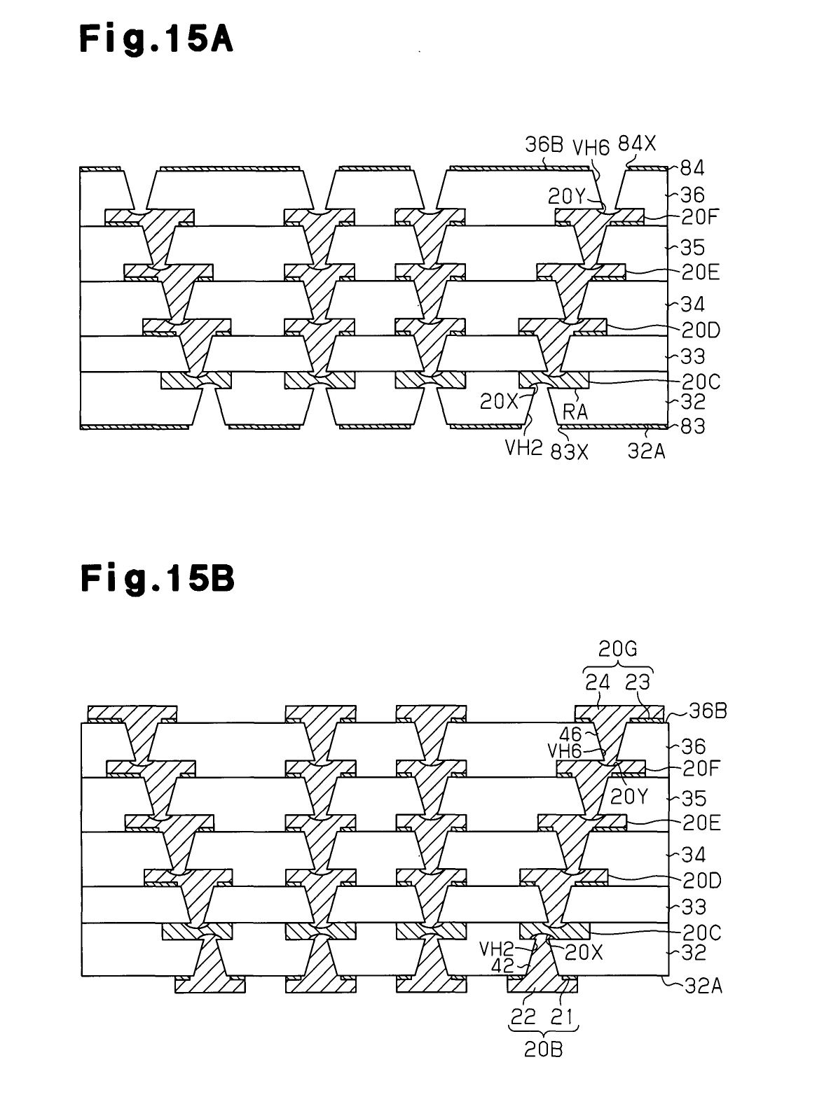

A manufacturing step similar to the step illustrated in FIG. 11D is then performed on the structure illustrated in FIG. 14C. According to such step, the metal foil 83 is etched so that the opening diameter of the opening 83X of the metal foil 83 is larger than the open end on the lower side of the through hole VH2, as illustrated in FIG. 15A. Furthermore, the recess 20X having a diameter larger than the open end on the upper side of the through hole VH2 is formed in the lower surface RA of the wiring layer 20C. Since the wiring layer 20C is thicker than the metal foil 83, the collar portion 83A of the metal foil 83 may be suitably removed even if the etching amount is increased. In this step, the metal foil 84 is etched so that the opening diameter of the opening 84X of the metal foil 84 becomes larger than the open end on the upper side of the through hole VH6, and the recess 20Y having a diameter larger than the open end on the lower side of the through hole VH6 is formed in the upper surface of the wiring layer 20F.

Manufacturing steps similar to the steps illustrated in FIG. 11E to FIG. 12C are then performed on the structure illustrated in FIG. 15A. According to such steps, the via 42 is filled in the through hole VH2 and the recess 20X, and the via 46 is filled in the through hole VH6 and the recess 20Y, as illustrated in FIG. 15B. The metal foil 83 is patterned to form the metal foil 21, and the wiring layer 20B including the metal foil 21 and the wiring pattern 22 is stacked on the lower surface 32A of the insulating layer 32. Furthermore, the metal foil 84 is patterned to form the metal foil 23, and the wiring layer 20G including the metal foil 23 and the wiring pattern 24 is stacked on the upper surface 36B of the insulating layer 36.

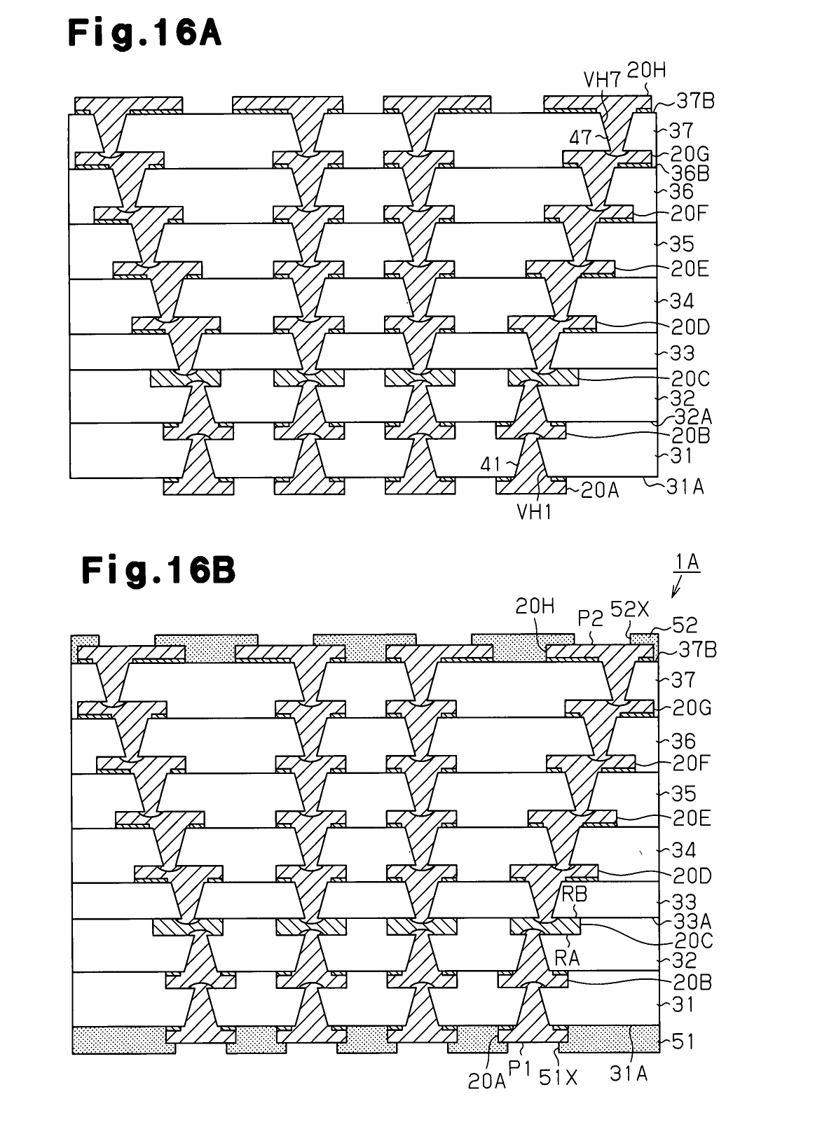

Manufacturing steps similar to the steps illustrated in FIG. 3E to FIG. 6A are then performed on the structure illustrated in FIG. 15B. According to such steps, the insulating layer 37 and the wiring layer 20H are sequentially stacked on the upper surface 36B of the insulating layer 36, and the insulating layer 31 and the wiring layer 20A are sequentially stacked on the lower surface 32A of the insulating layer 32, as illustrated in FIG. 16A.

In the step illustrated in FIG. 16B, the solder resist layer 51 having the opening 51X, which exposes the wiring layer 20A as the pad P1, at a given area is stacked on the lower surface 31A of the insulating layer 31. The solder resist layer 52 having the opening 52X, which exposes the wiring layer 20H as the external connection pad P2, at a given area is stacked on the upper surface 37B of the insulating layer 37.

A wiring substrate 1A having a structure that is substantially the same as the wiring substrate 1 may be manufactured according to the manufacturing steps described above. The wiring substrate 1A and the wiring substrate 1 differ in the structures of the wiring layer 20C and the insulating layers 32, 33. In the wiring substrate 1A, the wiring layer 20C is stacked on the lower surface 33A of the insulating layer 33, and the insulating layer 32 that covers the wiring layer 20C is stacked on the lower surface 33A of the insulating layer 33. In the wiring substrate 1A, on the other hand, the lower surface RA and the side surface of the wiring layer 20C are covered by the insulating layer 32, and the upper surface RB of the wiring layer 20C is covered by the insulating layer 33.

The second embodiment has the same advantages as the first embodiment.

It should be apparent to those skilled in the art that the present invention may be embodied in many other specific forms without departing from the spirit or scope of the invention. Particularly, it should be understood that the present invention may be embodied in the following forms.

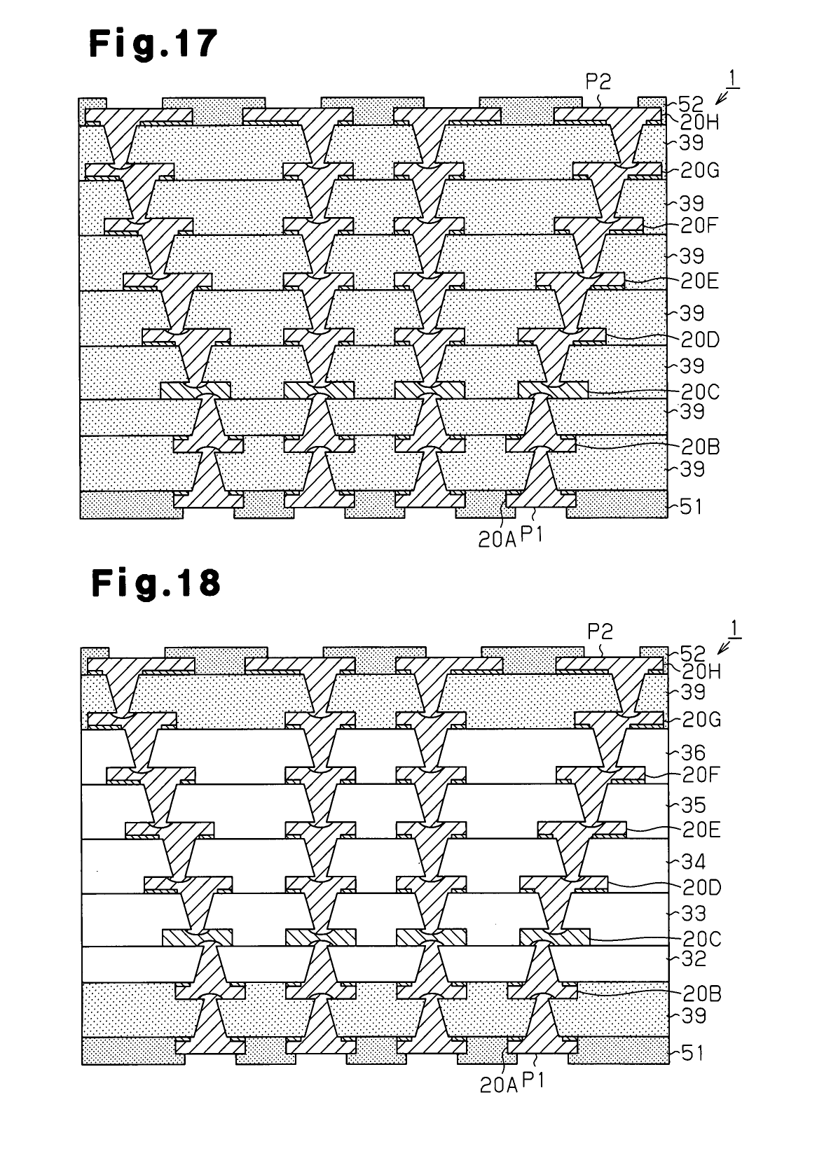

In each embodiment described above, the insulating layers 31 to 37 are all made from the insulating resin containing the reinforcement material, but the material of the insulating layers 31 to 37 is not limited to the insulating resin containing the reinforcement material. For example, the insulating layers 31 to 37 may all be changed to the insulating layer 39 that does not contain reinforcement material, as illustrated in FIG. 17. In this case, for example, the insulating resin such as epoxy resin, polyimide resin, and the like may be used for the material of the insulating layer 39. The thickness of the insulating layer 39 may be, for example, about 20 to 30 μm. According to such a structure, the thickness of each insulating layer 39 becomes thinner than the insulating layers 31 to 37 containing the reinforcement material, and thus the entire wiring substrate 1 may be thinned.

At least one of the insulating layers 31 to 37 may be the insulating layer containing the reinforcement material, and the remaining insulating layers may be the insulating layer not containing the reinforcement material. For example, as illustrated in FIG. 18, each of a plurality of (five in the present example) insulating layers 32 to 36 positioned near the center in the stacking direction may be changed to the insulating layer containing the reinforcement material, and the one or a plurality of insulating layers (herein, the lowermost insulating layer 31 and the uppermost insulating layer 37) positioned near the outermost layer may be changed to the insulating layer 39 not containing the reinforcement material. According to such a structure, the rigidity of the wiring substrate 1 near the center in the stacking direction may be enhanced. Furthermore, miniaturization of the wiring (narrower pitch of the pads P1, P2, etc.) may be easily responded since the thin insulating layer 39 is formed near the outermost layer.

Therefore, in the wiring substrate 1, 1A of each embodiment, an arbitrary insulating layer among the plurality of insulating layers 31 to 37 may be changed to the insulating layer not containing the reinforcement material. In other words, an arbitrary insulating layer may be easily changed to the insulating layer 39 not containing the reinforcement material according to the manufacturing method of the wiring substrate 1, 1A of each embodiment. That is, the material of each insulating layer may be appropriately set according to the properties (stacking number, thickness of layer, occupying area of wiring layer, etc.) of the wiring substrate.

In each embodiment described above, an example of forming one wiring substrate 1 or 1A on the support body 60 has been described, but a plurality of wiring substrates 1, 1A may be formed on the support body 60.

In each embodiment described above, the wiring layer and the insulating layer are stacked on one side (upper surface) of the support body 60 using the build-up construction method, and then the support body 60 is removed to obtain one structure illustrated in FIG. 7A and FIG. 13B. This is not the sole case, and the wiring layer and the insulating layer may be stacked on both sides (upper surface and lower surface) of the support body 60 using the buildup construction method, for example, and then the support body 60 may be removed to obtain a plurality of the structure illustrated in FIG. 7A and FIG. 13B.

In the wiring substrate 1, 1A of each embodiment described above, a surface on which the pad P1 is formed is the chip mounting surface. Instead, for example, a surface on which the external connection pad P2 is formed may serve as the chip mounting surface.

In each embodiment described above, an example that mounts the semiconductor chip 10 on the wiring substrate 1 has been described. However, the mounting component is not limited to the semiconductor chip 10. For example, each embodiment described above may also be applied to a package (package on package) having a structure in which another wiring substrate is stacked on the wiring substrate 1.

The number of layers and the drawing of wiring of the wiring substrate 1, 1A in each embodiment described above, the mounting mode (e.g., flip-chip mounting, wire bonding mounting, or combination thereof) of the semiconductor chip 10, and the like may be variously modified and changed.

Clauses

This disclosure further encompasses various embodiments described below.

1. A method for manufacturing a wiring substrate, the method comprising:

(a) preparing a support body;

(b) sequentially stacking a first metal foil, a first insulating layer, and a second metal foil on a first surface of the support body, wherein the second metal foil is thicker than the first metal foil;

(c) forming a first wiring layer by patterning the second metal foil;

(d) stacking a second insulating layer, which covers the first wiring layer, on the first insulating layer;

(e) stacking a third metal foil, which is thinner than the second metal foil, on the second insulating layer;

(f) forming a first opening in the third metal foil and a first through hole in the second insulating layer by performing laser processing, wherein the first through hole is in communication with the first opening and extends through the second insulating layer to expose a first surface of the first wiring layer, and the first through hole includes a first open end and a second open end, which is located at an opposite side of the first open end and faces the first surface of the first wiring layer;

(g) forming a first recess that is in communication with the first through hole in the first surface of the first wiring layer while removing the third metal foil projecting above the first through hole, wherein the first recess has a diameter that is larger than an opening diameter of the second open end of the first through hole;

(h) forming a first via, which fills the first through hole and the first recess, and a first conductive layer, which covers the first via and the third metal foil;

(i) forming a second wiring layer on the second insulating layer, wherein the second wiring layer includes a fourth metal foil and a first wiring pattern, which are obtained by patterning the third metal foil and the first conductive layer, and the second wiring layer is electrically connected to the first via;

(j) removing the support body after step (i);

(k) forming a second opening in the first metal foil and a second through hole in the first insulating layer by performing laser processing after step (j), wherein the second through hole is in communication with the second opening and extends through the first insulating layer to expose a second surface of the first wiring layer located at an opposite side of the first surface of the first wiring layer, and the second through hole includes a third open end and a fourth open end, which is located at an opposite side of the third open end and faces the second surface of the first wiring layer;

(l) forming a second recess that is in communication with the second through hole in the second surface of the first wiring layer while removing the first metal foil projecting above the second through hole, wherein the second recess has a diameter that is larger than an opening diameter of the fourth open end of the second through hole;

(m) forming a second via that fills the second through hole and the second recess, and a second conductive layer that covers the second via and the first metal foil; and

(n) forming a third wiring layer on the first insulating layer, wherein the third wiring layer includes a fifth metal foil and a second wiring pattern, which are obtained by patterning the first metal foil and the second conductive layer, and the third wiring layer is electrically connected to the second via, wherein

the opening diameter of the second open end of the first through hole is smaller than an opening diameter of the first open end, and

the opening diameter of the fourth open end of the second through hole is smaller than an opening diameter of the third open end.

2. The method according to clause 1, further comprising after step (i) and before step (j):

alternately stacking a given number of third insulating layers and a given number of fourth wiring layers on the second insulating layer by repeating steps (e) to (i) a given number of times;

stacking a fourth insulating layer on an outermost one of the third insulating layers, wherein the fourth insulating layer has a thickness that is the same as the first insulating layer and covers an outermost one of the third wiring layers; and

stacking a sixth metal foil on the fourth insulating layer, wherein the sixth metal foil has a thickness that is the same as the first metal foil;

the method further comprising after step (j):

forming a third opening in the sixth metal foil and a third through hole in the fourth insulating layer by performing laser processing, wherein the third through hole is in communication with the third opening and extends through the fourth insulating layer to expose the outermost one of the fourth wiring layers, and the third through hole includes a fifth open end and a sixth open end, which is located at an opposite side of the fifth open end and faces a first surface of the outermost one of the fourth wiring layers;

forming a third recess in the first surface of the outermost one of the fourth wiring layers while removing the sixth metal foil projecting above the third through hole, wherein the third recess is in communication with the third through hole and has a diameter that is larger than an opening diameter of the sixth open end of the third through hole;

forming a third via, which fills the third through hole and the third recess, and a third conductive layer, which covers the third via and the sixth metal foil; and

forming a fifth wiring layer on the fourth insulating layer, wherein the fifth wiring layer includes a seventh metal foil and a third wiring pattern, which are obtained by patterning the sixth metal foil and the third conductive layer, and the fifth wiring layer is electrically connected to the third via.

3. The method according to clause 1, wherein

each of the first and second insulating layers is an insulating resin layer containing a reinforcement material;

step (h) includes forming the first via to cover the reinforcement material of the second insulating layer projecting to an inner side from an inner wall of the first through hole; and

step (m) includes forming the second via to cover the reinforcement material of the first insulating layer projecting to an inner side from an inner wall of the second through hole.

4. A method for manufacturing a wiring substrate, the method comprising:

(a) preparing a support body;

(b) sequentially stacking a first metal foil, a first insulating layer, and a second metal foil on a first surface of the support body, wherein the second metal foil is thinner than the first metal foil;

(c) forming a first opening in the second metal foil and a first through hole in the first insulating layer by performing laser processing, wherein the first through hole is in communication with the first opening and extends through the first insulating layer to expose a first surface of the first metal foil, and the first through hole includes a first open end and a second open end, which is located at an opposite side of the first open end and faces the first surface of the first metal foil;

(d) forming a first recess in the first surface of the first metal foil while removing the second metal foil projecting above the first through hole, wherein the first recess is in communication with the first through hole and has a diameter that is larger than an opening diameter of the second open end of the first through hole;

(e) forming a first via, which fills the first through hole and the first recess, and a first conductive layer, which covers the first via and the second metal foil;

(f) forming a first wiring layer on a first surface of the first insulating layer, wherein the first wiring layer includes a third metal foil and a first wiring pattern, which are obtained by patterning the second metal foil and the first conductive layer, and the first wiring layer is electrically connected to the first via;

(g) removing the support body after step (f);

(h) forming a second wiring layer by patterning the first metal foil;

(i) stacking a second insulating layer, which covers the second wiring layer, on a second surface of the first insulating layer located at an opposite side of the first surface of the first insulating layer;

(j) stacking a fourth metal foil, which is thinner than the first metal foil, on the second insulating layer;

(k) forming a second opening in the fourth metal foil and a second through hole in the second insulating layer by performing laser processing, wherein the second through hole is in communication with the second opening and extends through the second insulating layer to expose a first surface of the second wiring layer, and the second through hole includes a third open end and a fourth open end, which is located at an opposite side of the third open end and faces the first surface of the second wiring layer;

(l) forming a second recess that is in communication with the second through hole in the first surface of the second wiring layer while removing the fourth metal foil projecting above the second through hole, wherein the second recess has a diameter that is larger than an opening diameter of the fourth open end of the second through hole;

(m) forming a second via, which fills the second through hole and the second recess, and a second conductive layer, which covers the second via and the fourth metal foil; and

(n) forming a third wiring layer on the second insulating layer, wherein the third wiring layer includes a fifth metal foil and a second wiring pattern, which are obtained by patterning the fourth metal foil and the second conductive layer, and the third wiring layer is electrically connected to the second via, wherein

the opening diameter of the second open end of the first through hole is smaller than an opening diameter of the first open end, and

the opening diameter of the fourth open end of the second through hole is smaller than an opening diameter of the third open end.

5. The method according to clause 4, further comprising, after step (f) and before step (g):

(o) stacking a third insulating layer, which covers the first wiring layer, on the first surface of the first insulating layer;

(p) staking a sixth metal foil, which is thinner than the first metal foil, on the third insulating layer;

(q) alternately stacking a given number of fourth wiring layers and a given number of fourth insulating layers on the third insulating layer by repeating steps (c) to (f), (o), and (p) a given number of times;

(r) forming a third opening in a seventh metal foil, which is formed on an outermost one of the fourth insulating layers, and a third through hole in the outermost one of the fourth insulating layers by performing laser processing, wherein the third through hole is in communication with the third opening and extends through the outermost one of the fourth insulating layers to expose an outermost one of the fourth wiring layers, wherein the third through hole includes a fifth open end and a sixth open end, which is located at an opposite side of the fifth open end and faces the outermost one of the fourth wiring layers;

(s) forming a third recess, which is in communication with the third through hole, in the outermost one of the fourth wiring layers while removing the seventh metal foil projecting above the third through hole, wherein the third recess has a diameter that is larger than an opening diameter of the sixth open end of the third through hole; and

(t) forming a third via, which fills the third through hole and the third recess, and a third conductive layer, which covers the third via and the seventh metal foil,

the method further comprising after step (g):

forming a fifth wiring layer by patterning the seventh metal foil and the third conductive layer, wherein

the third conductive layer and the seventh metal foil have a total thickness that is set to be the same as a thickness of the first metal foil.

6. The method according to clause 5, further comprising:

stacking a fifth insulating layer, which covers the fifth wiring layer, on a first surface of the outermost one of the fourth insulating layers;

stacking an eighth metal foil, which is thinner than the first metal foil, on the fifth insulating layer;

forming a fourth opening in the eighth metal foil and a fourth through hole in the fifth insulating layer by performing laser processing, wherein the fourth through hole is in communication with the fourth opening and extends through the fifth insulating layer to expose the fifth wiring layer, and the fourth through hole includes a seventh open end and an eighth open end, which is located at an opposite side of the seventh open end and faces the fifth wiring layer;

forming a fourth recess, which is in communication with the fourth through hole, in the fifth wiring layer while removing the eighth metal foil projecting above the fourth through hole, wherein the fourth recess has a diameter that is larger than an opening diameter of the eighth open end of the fourth through hole;

forming a fourth via, which fills the fourth through hole and the fourth recess, and a fourth conductive layer, which covers the fourth via and the eighth metal foil; and

forming a sixth wiring layer on the fifth insulating layer, wherein the sixth wiring layer includes a ninth metal foil and a third wiring pattern, which are obtained by patterning the eighth metal foil and the fourth conductive layer, and the sixth wiring layer is electrically connected to the fourth via.

The present examples and embodiments are to be considered as illustrative and not restrictive, and the invention is not to be limited to the details given herein, but may be modified within the scope and equivalence of the appended claims.

1. A wiring substrate comprising:
a first wiring layer that is a single metal layer;
a first insulating layer arranged on an upper surface of the first wiring layer;
a second wiring layer arranged on the first insulating layer, wherein the second wiring layer includes a first metal foil, which is thinner than the first wiring layer, and a first wiring pattern;
a second insulating layer arranged on a lower surface of the first wiring layer;
a third wiring layer arranged on the second insulating layer, wherein the third wiring layer includes a second metal foil, which is thinner than the first wiring layer, and a second wiring pattern;
a first via arranged in the first insulating layer to electrically connect the first wiring layer and the second wiring layer; and
a second via arranged in the second insulating layer to electrically connect the first wiring layer and the third wiring layer; wherein:
the first via is arranged to fill a first through hole and a first recess, wherein
the first through hole extends through the first insulating layer, and the first through hole includes a first open end, which faces the second wiring layer and has a first opening diameter, and a second open end, which faces the first wiring layer and has a second opening diameter, the second opening diameter being smaller than the first opening diameter, and
the first recess is arranged in the upper surface of the first wiring layer in communication with the first through hole, the first recess having a diameter that is larger than the second opening diameter;
the second via is arranged to fill a second through hole and a second recess, wherein
the second through hole extends through the second insulating layer, and the second through hole includes a third open end, which faces the third wiring layer and has a third opening diameter, and a fourth open end, which faces the first wiring layer and has a fourth opening diameter, the fourth opening diameter being smaller than the third opening diameter, and
the second recess is arranged in the lower surface of the first wiring layer in communication with the second through hole, the second recess having a diameter that is larger than the fourth opening diameter;
the first metal foil includes a first opening, which is in communication with the first through hole and has an opening diameter that is larger than or equal to the first opening diameter; and
the second metal foil includes a second opening, which is in communication with the second through hole and has an opening diameter that is larger than or equal to the third opening diameter.

2. The wiring substrate according to claim 1, further comprising:
a third insulating layer arranged on an upper surface of the first insulating layer to cover the second wiring layer;
a fourth wiring layer arranged on an upper surface of the third insulating layer, wherein the fourth wiring layer includes a third metal foil, which is thinner than the second wiring layer, and a third wiring pattern;
a fourth insulating layer arranged on a lower surface of the second insulating layer to cover the third wiring layer;
a fifth wiring layer arranged on a lower surface of the fourth insulating layer, wherein the fifth wiring layer includes a fourth metal foil, which is thinner than the third wiring layer, and a fourth wiring pattern;
a third via arranged in the third insulating layer to electrically connect the second wiring layer and the fourth wiring layer; and
a fourth via arranged in the fourth insulating layer to electrically connect the third wiring layer and the fifth wiring layer; wherein:
the third insulating layer includes a third through hole that extends through the third insulating layer, and the third through hole includes a fifth open end, which faces the fourth wiring layer and has a fifth opening diameter, and a sixth open end, which faces the second wiring layer and has a sixth opening diameter that is smaller than the fifth opening diameter;
the fourth insulating layer includes a fourth through hole that extends through the fourth insulating layer, and the fourth through hole includes a seventh open end, which faces the fifth wiring layer and has a seventh opening diameter, and an eighth open end, which faces the third wiring layer and has an eighth opening diameter that is smaller than the seventh opening diameter;
the second wiring layer includes a third recess arranged in an upper surface of the second wiring layer in communication with the third through hole, and the third recess has a diameter that is larger than the sixth opening diameter;
the third wiring layer includes a fourth recess arranged in a lower surface of the third wiring layer in communication with the fourth through hole, and the fourth recess has a diameter that is larger than the eighth opening diameter;
the third via is filled in the third through hole and the third recess; and
the fourth via is filled in the fourth through hole and the fourth recess.

3. The wiring substrate according to claim 2, wherein
each of the first to fourth insulating layers is an insulating resin layer containing a reinforcement material; and
the first to fourth vias entirely cover ends of the reinforcement materials projecting toward an inner side from inner walls of the first to fourth through holes, respectively.

4. The wiring substrate according to claim 1, further comprising:
a first outermost insulating layer arranged above the first insulating layer; and
a second outermost insulating layer arranged below the second insulating layer,
wherein the second outermost insulating layer includes a surface that is flatter than the first outermost insulating layer.
